(19) United States
(12) Patent Application Publication
(10) Pub. No.: US 2025/0349653 A1
(43) Pub. Date: Nov. 13, 2025

(54) STRUCTURE AND FORMATION METHOD OF PACKAGE WITH HEAT-SPREADING LID

(71) Applicant: Taiwan Semiconductor Manufacturing Company, Ltd., Hsinchu (TW)

(72) Inventors: Chen-Hsuan TSAI, Taitung City (TW); Chih-Hao CHEN, Taipei city (TW); Chin-Chuan CHANG, Zhudong Township (TW); Ying-Ching SHIH, Hsinchu City (TW)

(21) Appl. No.: 18/659,650

(22) Filed: May 9, 2024

(51) Int. Cl. H01L 23/367; H01L 21/603; H01L 23/00; H01L 23/31; H01L 23/498; H01L 25/16

(52) U.S. Cl. CPC H01L 23/3675; H01L 21/603; H01L 23/3121; H01L 23/49838; H01L 25/16; H01L 24/16; H01L 2224/16238; H01L 2924/1431; H01L 2924/1436

(57) ABSTRACT

A package structure and a formation method are provided. The method includes disposing a chip-containing structure over a substrate and forming a thermal conductive layer over the chip-containing structure. The method also includes disposing a heat-spreading lid over the chip-containing structure and the thermal conductive layer. A metallic structure is embedded in the heat-spreading lid, and the metallic structure faces the thermal conductive layer. The method further includes pressing the heat-spreading lid against the chip-containing structure at an elevated temperature such that a portion of or an entirety of the metallic structure and a portion of or an entirety of the thermal conductive layer are transformed into an intermetallic compound material.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A package structure not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges. For example, the heat dissipation of the package structure becomes more important.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1G are cross-sectional views of various stages of a process for forming a portion of a package structure, in accordance with some embodiments.

FIG. 2 is a plan view of an intermediate stage of a process for forming a portion of a package structure, in accordance with some embodiments.

FIG. 3 is a plan view of an intermediate stage of a process for forming a portion of a package structure, in accordance with some embodiments.

FIGS. 4A-4C are cross-sectional views of various stages of a process for forming a portion of a package structure, in accordance with some embodiments.

FIGS. 5A-5B are cross-sectional views of various stages of a process for forming a portion of a package structure, in accordance with some embodiments.

FIGS. 6A-6B are cross-sectional views of various stages of a process for forming a portion of a package structure, in accordance with some embodiments.

FIGS. 7A-7B are cross-sectional views of various stages of a process for forming a portion of a package structure, in accordance with some embodiments.

FIG. 8 is a plan view of an intermediate stage of a process for forming a portion of a package structure, in accordance with some embodiments.

FIG. 9A is a cross-sectional view of a portion of a package structure, in accordance with some embodiments.

FIG. 9B is a cross-sectional view of a portion of a package structure, in accordance with some embodiments.

FIGS. 10A-10B are plan views of various stages of a process for forming a portion of a package structure, in accordance with some embodiments.

FIGS. 11A-11C are cross-sectional views of various stages of a process for forming a portion of a package structure, in accordance with some embodiments.

FIGS. 12A-12B are plan views of various stages of a process for forming a portion of a package structure, in accordance with some embodiments.

FIGS. 13A-13C are cross-sectional views of various stages of a process for forming a portion of a package structure, in accordance with some embodiments.

FIGS. 14A-14B are plan views of various stages of a process for forming a portion of a package structure, in accordance with some embodiments.

FIGS. 15A-15C are cross-sectional views of various stages of a process for forming a portion of a package structure, in accordance with some embodiments.

FIG. 16A is a plan view of an intermediate stage of a process for forming a portion of a package structure, in accordance with some embodiments.

FIG. 16B is a plan view of an intermediate stage of a process for forming a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows the testing through probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

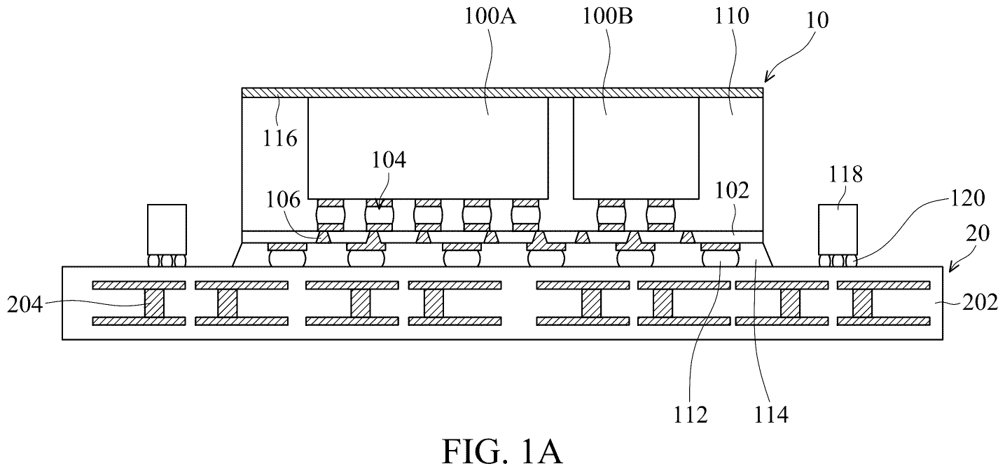

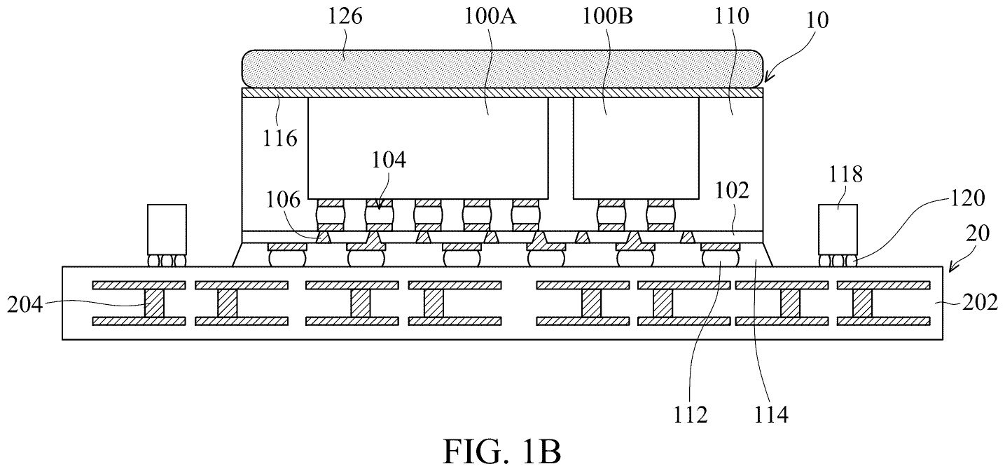

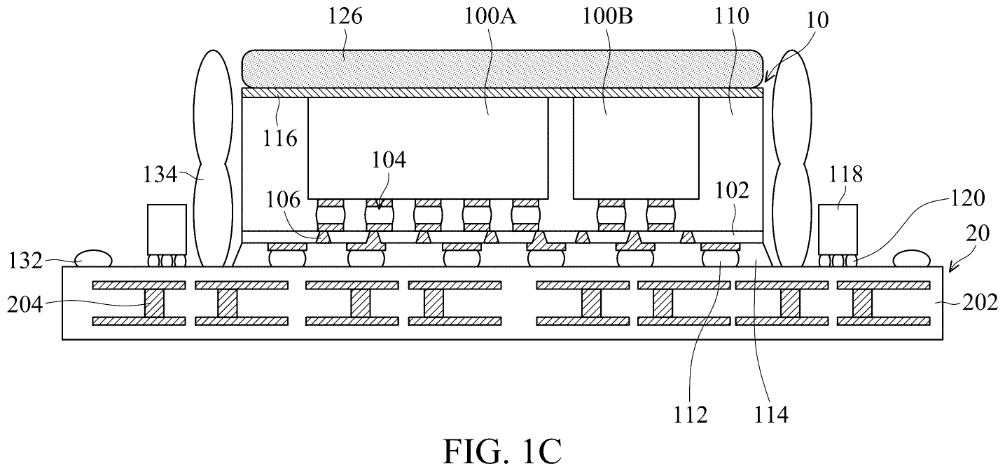

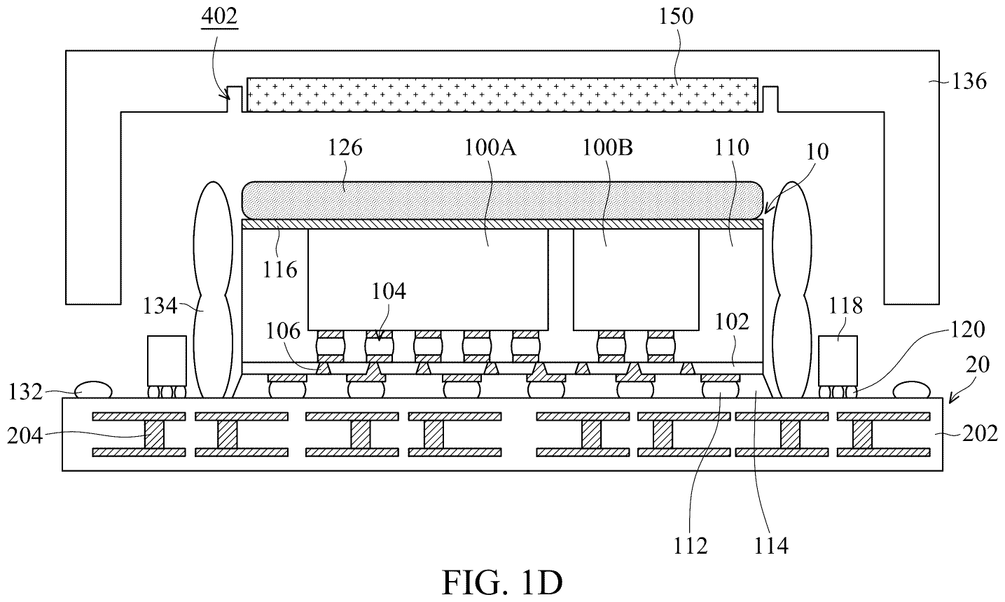

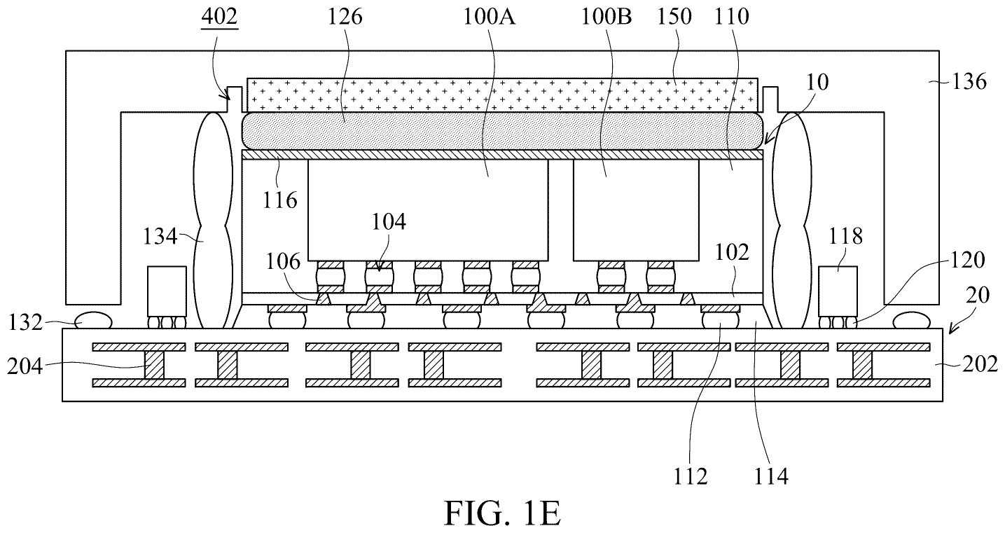

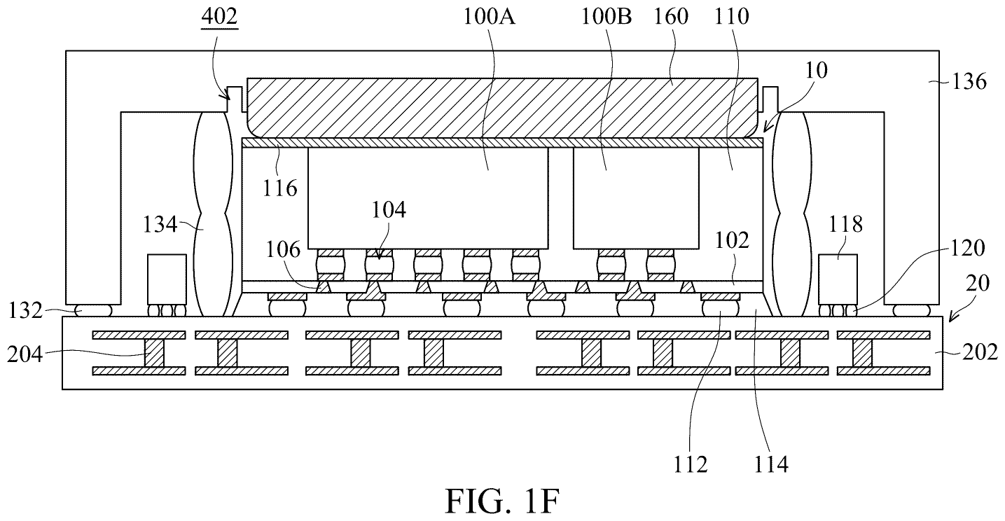

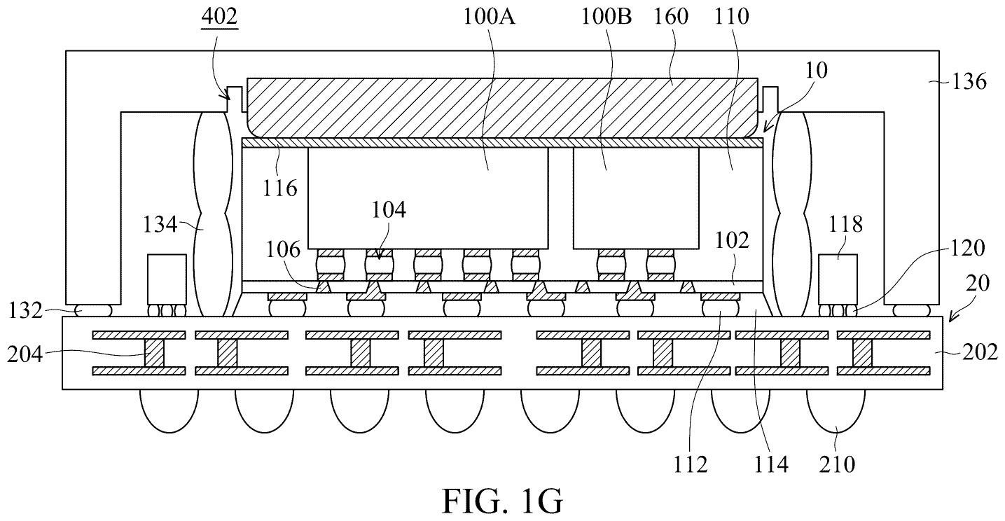

FIGS. 1A-1G are cross-sectional views of various stages of a process for forming a portion of a package structure, in accordance with some embodiments. As shown in FIG. 1A, a chip package 10 is disposed over a substrate 20, in accordance with some embodiments. In some embodiments, the chip package 10 is bonded to the substrate 20 through multiple bonding structures 112. The bonding structures 112 may be made of or include solder material. The solder material may be a tin-containing material. The tin-containing material may further include copper, silver, gold, aluminum, lead, one or more other suitable materials, or a combination thereof. In some other embodiments, the solder material is lead-free.

In some embodiments, an underfill structure 114 is formed to laterally surround and protect the bonding structures 112, as shown in FIG. 1A. A portion of the underfill structure 114 is between the substrate 20 and the bottom of the chip package 10. A second portion of the underfill structure 114 may extend upwards along sidewalls of the chip package 10. The underfill structure 114 may be made of or include an epoxy-based resin with fillers dispersed therein. The fillers may include fibers (such as silica fibers and/or carbon-containing fibers), particles (such as silica particles and/or carbon-containing particles), or a combination thereof.

In some embodiments, an underfill liquid is dispensed onto the substrate 20 along a side of the chip package 10. The underfill liquid may be made of or include a polymer material, such as an epoxy-based resin with fillers dispersed therein. The fillers may include fibers (such as silica fibers and/or carbon-containing fibers), particles (such as silica particles and/or carbon-containing particles), or a combination thereof. The underfill liquid may be drawn into the space between the substrate 20 and the chip package 10, so as to surround the bonding structures 112 by the capillary force. Afterwards, a thermal operation may be used to cure the underfill liquid. As a result, the underfill structure 114 is formed.

In some embodiments, the chip package 10 contains multiple chip structures (or chip-containing structures). As shown in FIG. 1A, the chip package 10 includes chip structures 100A and 100B. Each of the chip structures 100A and 100B may be a single semiconductor die and/or system-on-integrated-chips (SoIC). For the system-on-integrated-chips, multiple semiconductor dies (or chiplets) are stacked and bonded together to form electrical connections between these semiconductor dies (or chiplets). In some embodiments, the semiconductor dies are system-on-chip (SoC) chips that include multiple functions. In some embodiments, one or more of the chip structures 100A and 100B include high-frequency devices, optoelectronic devices, photonic devices, logic devices, memory devices, one or more other suitable devices, or a combination thereof. In some embodiments, the chip structure 100B includes multiple memory devices and is used as a memory chip structure. In some embodiments, the chip structure 100B is used as a high bandwidth memory (HBM). In some embodiments, the chip structure 100A includes multiple logic devices and is used as a logic chip structure.

In some embodiments, the chip package 10 includes an interposer substrate 102, as shown in FIG. 1A. In some embodiments, the chip structures 100A and 100B are bonded to the interposer substrate 102 through multiple bonding structures 104. Each of the bonding structures 104 may include a conductive pillar (such as a copper pillar) and a tin-containing solder bump. An underfill structure may be formed over the interposer substrate 102, so as to laterally surround and protect the bonding structures 104. The material and formation method of the underfill structure may be the same as or similar to those of the underfill structure 114. In some other embodiments, the underfill structure is not formed.

In some embodiments, a protective layer 110 is formed over the interposer substrate 102 to encapsulate and protect the chip structures 100A and 100B. The protective layer 110 may be made of or include a molding material. The protective layer 110 may be made of or include an epoxy-based resin with fillers dispersed therein. The fillers may include insulating fibers, insulating particles, one or more other suitable elements, or a combination thereof. In some embodiments, the average size of the fillers in the protective layer 110 is larger than that of the fillers in the underfill structure 114. In some embodiments, the weight percentage of the fillers in the protective layer 110 is greater than that of the fillers in the underfill structure 114.

In some embodiments, the interposer substrate 102 is a semiconductor substrate (such as a silicon substrate) that includes multiple through substrate vias (TSVs) 106 formed therein. The through substrate vias 106 may provide electrical connections between the elements (such as the chip structures 100A and 100B) above the interposer substrate 102 and the elements (such as the bonding structures 112) below the interposer substrate 102.

However, embodiments of the disclosure are not limited thereto. Many variations and/or modifications can be made to embodiments of the disclosure. In some other embodiments, the interposer substrate 102 is a redistribution structure that includes a polymer-based substrate. The polymer-based substrate includes multiple conductive features formed therein. In some other embodiments, the interposer substrate 102 includes a polymer-based substrate and an interconnection die embedded in or surrounded by the polymer-based substrate.

In some embodiments, a backside metallization layer 116 is formed over the surfaces of the protective layer 110 and the chip structures 100A and 100B, as shown in FIG. 1A. The backside metallization layer 116 may function as an adhesive layer that helps to improve the adhesion between a subsequently disposed thermal conductive layer and the chip package 10. The backside metallization layer 116 may be made of or include aluminum, titanium, gold, nickel, copper, palladium, vanadium, nickel-vanadium alloy, another suitable material, or a combination thereof.

As shown in FIG. 1A, one or more surface-mounted devices 118 are disposed over the substrate 20, in accordance with some embodiments. In some embodiments, the surface-mounted devices 118 are bonded to the substrate 20 through bonding structures 120. Each of the surface-mounted devices 118 is laterally spaced apart from the chip package 10, as shown in FIG. 1A.

Each of the surface-mounted devices 118 may include one or more passive devices such as resistors, capacitors, insulators, other suitable devices, or a combination thereof. In some other embodiments, the surface-mounted devices 118 include one or more active devices such as transistor devices, diode devices, other suitable devices, or a combination thereof. In some other embodiments, one or more of the surface-mounted devices 118 include a combination of passive devices and active devices.

In some embodiments, the substrate 20 is a circuit board that includes multiple insulating layers 202 and multiple conductive features 204 that are surrounded by the insulating layers 202. The conductive features 204 may include conductive lines and conductive vias.

In some embodiments, a flux material is provided on the backside metallization layer 116, in accordance with some embodiments. The flux material may assist in a subsequent disposing of the thermal conductive layer. In some embodiments, a flux jetting operation is performed using a flux provider, so as to provide the flux material on the backside metallization layer 116. The flux material may include one or more rosin, one or more acids, one or more alkalis, one or more solvents, another suitable material, or a combination thereof.

As shown in FIG. 1B, a thermal conductive layer 126 is disposed over the chip package 10, in accordance with some embodiments. In some embodiments, the thermal conductive layer 126 is made of or include a metal material. In some embodiments, the thermal conductive layer 126 is made of or include a metal material that has a low melting point and has a low stress. The thermal conductive layer 126 may have suitable fluidity when being heated at an elevated temperature that is around the low melting point of the thermal conductive layer 126.

In some embodiments, the thermal conductive layer 126 has a melting point that is lower than about 160 degrees C. In some embodiments, the thermal conductive layer 126 has a melting point that is within a range from about 50 degrees C. to about 160 degrees C. The thermal conductive layer 126 may be an indium-based material, a gallium-based material, another suitable material, or a combination thereof. In some embodiments, the thermal conductive layer 126 is an indium layer.

As shown in FIG. 1C, one or more adhesive structures 132 are formed over the substrate 20, in accordance with some embodiments. In some embodiments, an adhesive provider is used to dispense an adhesive material over the substrate 20 at predetermined regions. The adhesive material dispensed over the predetermined regions form the adhesive structures 132. The adhesive structures 132 may be made of an epoxy-based glue, a silicone-based glue, another suitable glue, or a combination thereof. In some embodiments, the adhesive structures 132 laterally surround the surface-mounted devices 118 and the chip package 10.

As shown in FIG. 1C, an inner adhesive structure 134 is formed over the substrate 20, in accordance with some embodiments. Similar to the formation of the adhesive structure 132, an adhesive provider may be used to assist in the formation of the inner adhesive structure 134. In some embodiments, the inner adhesive structure 134 laterally surrounds the chip package 10. In some embodiments, the inner adhesive structure 134 is positioned between the chip package 10 and the surface-mounted device 118.

In some embodiments, the inner adhesive structure 134 has a lower portion and an upper portion, in accordance with some embodiments. In some embodiments, an adhesive provider may be used to form the lower portion and the upper portion of the inner adhesive structure 134 separately. The lower portion and the upper portion that is formed after the lower portion together form the inner adhesive structure 134. In some embodiments, the inner adhesive structure 134 laterally surrounds the chip package 10. In some embodiments, the inner adhesive structure 134 laterally surrounds the thermal conductive layer 126 that is placed over the chip package 10.

As shown in FIG. 1D, a heat-spreading lid 136 is disposed over the chip package 10 and the substrate 20, in accordance with some embodiments. In some embodiments, a metallic structure 150 is formed on the heat-spreading lid 136. In some embodiments, the metallic structure 150 is a patterned metallic structure that is embedded in the main body of the heat-spreading lid 136. In some embodiments, the metallic structure 150 faces the thermal conductive layer 126, as shown in FIG. 1D.

The main body of the heat-spreading lid 136 may be made of or include copper, steel, nickel, aluminum, another suitable material, or a combination thereof. The metallic structure 150 may be made of or include gold, silver, tin, zinc, another suitable material, or a combination thereof. In some embodiments, one or more recesses with desired profiles and distributions are formed in the main body of the heat-spreading lid 136. Afterwards, a metal layer is deposited to fill the recesses. The portions of the metal layer that are outside of the recesses may then be removed. As a result, the remaining portion of the metal layer forms the metallic structure 150.

In some embodiments, the heat-spreading lid 136 includes one or more trenches 402, as shown in FIG. 1D. In some embodiments, a portion of the thermal conductive layer 126 may extend into the trenches 402 after the heat-spreading lid 136 is bonded to the substrate 20. The trenches 402 may contain a portion of the thermal conductive layer 126 and help to keep the thermal conductive layer 126 within the predetermined region. The thermal conductive layer 126 may thus be prevented from reaching and negatively affecting other elements (such as the surface-mounted devices 118) nearby.

However, embodiments of the disclosure are not limited thereto. Many variations and/or modifications can be made to embodiments of the disclosure. In some other embodiments, the trenches 402 are not formed.

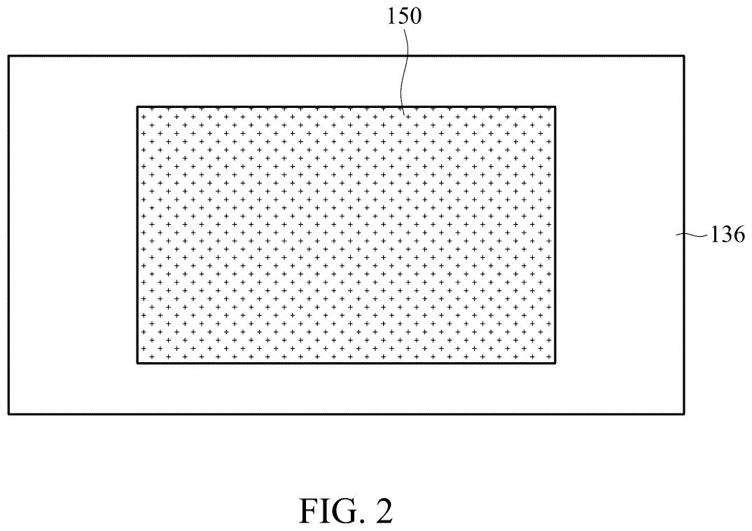

FIG. 2 is a plan view of an intermediate stage of a process for forming a portion of a package structure, in accordance with some embodiments. In some embodiments, FIG. 2 shows the plan view of the portion of the heat-spreading lid 136 near the metallic structure 150. The trenches 402 are not shown in FIG. 2 for simplicity and clarity. In some embodiments, the metallic structure 150 has a rectangular profile or a square profile. In some embodiments, the metallic structure 150 extends across the opposite edges of the chip structure 100A and the opposite edges of the chip structure 100B.

As shown in FIG. 1E, the heat-spreading lid 136 is lowered, in accordance with some embodiments. As a result, the metallic structure 150 is in direct contact with the thermal conductive layer 126. An interface between the metallic structure and the thermal conductive layer 126 is thus formed, as shown in FIG. 1E. In some embodiments, the heat-spreading lid 136 is in direct contact with the inner adhesive structure 134, as shown in FIG. 1E.

Afterwards, the heat-spreading lid 136 is pressed against the thermal conductive layer 126 and the inner adhesive structure 134 at an elevated temperature. As a result, the structure shown in FIG. 1F is formed, in accordance with some embodiments. In some embodiments, the heat-spreading lid 136 and the substrate 20 that carries the chip package 10 are bonded together using a heat clamping process. The elevated temperature may be within a range from about 130 degrees C. to about 200 degrees C. As shown in FIG. 1F, the adhesive structures 132 and the inner adhesive structure 134 may help to adhere the heat-spreading lid 136 to the substrate 20.

In some embodiments, under the thermal compression, the metallic structure 150 and the thermal conductive layer 126 are transformed into an alloy structure 160, as shown in FIG. 1F. The alloy structure 160 may function as a thermal conductive structure and a bonding structure that provides strong adhesion between the chip package 10 and the heat-spreading lid 136. The alloy structure 160 may include an intermetallic compound material, a substitutional alloy material, an interstitial alloy material, a two-phase alloy material, another suitable alloy material, or a combination thereof. In some embodiments, the alloy structure 160 extends into the heat-spreading lid 136, as shown in FIG. 1F. In some embodiments, the topmost surface of the alloy structure 160 is higher than an interface between the heat-spreading lid 136 and the inner adhesive structure 134.

The alloy structure 160 may be made of or include a compound material that contains Au—In, Ag—In, Sn—In, Zn—In, another suitable material, or a combination thereof. In some embodiments, the alloy structure 160 includes an intermetallic compound material that contains first metallic elements from the thermal conductive layer 126 (such as indium) and second metallic elements from the metallic structure 150 (such as gold, silver, tin, or zinc).

In some embodiments, the metallic structure 150 and the thermal conductive layer 126 are heated for a long period of time to ensure fully reaction between the metallic structure 150 and the thermal conductive layer 126. In some embodiments, the metallic structure 150 and the thermal conductive layer 126 are heated at a temperature around 200 degrees C. for more than 4 hours. As a result, the entirety of the metallic structure 150 and the entirety of the thermal conductive layer 126 are transformed into the alloy structure 160.

However, embodiments of the disclosure are not limited thereto. Many variations and/or modifications can be made to embodiments of the disclosure. In some other embodiments, the metallic structure 150 and the thermal conductive layer 126 are not heated for a long period of time. As a result, the metallic structure 150 and the thermal conductive layer 126 are partially transformed into the alloy structure 160.

In some embodiments, a portion of the thermal conductive layer 126 and a portion of the metallic structure 150 are transformed into the alloy structure 160. In some embodiments, the portion of the thermal conductive layer 126 and the portion of the metallic structure 150 that are near the original interface between the thermal conductive layer 126 and the metallic structure 150 are transformed into the alloy structure 160. In some embodiments, the alloy structure 160 is formed between the remaining portion of the thermal conductive layer 126 and the remaining portion of the metallic structure 150. In some other embodiments, a portion of the thermal conductive layer 126 and the entirety of the metallic structure 150 together form the alloy structure 160. In some embodiments, the alloy structure 160 is formed between the remaining portion of the thermal conductive layer 126 and the heat-spreading lid 136.

In some embodiments, because the metallic structure 150 and the thermal conductive layer 126 together form the alloy structure 160, the adhesion between the heat-spreading lid 136 and the chip package 10 is greatly improved. Because the alloy structure 160 forms, the thermal conductive layer 126, which could flow during the heat clamping process, may be prevented from flowing away from the chip package 10. Due to good joint between the chip package 10 and the heat-spreading lid 136, heat generated from the chip structures 100A and 100B may thus be led out efficiently through the heat-spreading lid 136. The performance and reliability of the package structure are greatly improved.

Afterwards, as shown in FIG. 1G, multiple bonding structures 210 are formed on the bottom of the substrate 20, in accordance with some embodiments. The bonding structures 210 may include tin-containing solder bumps. The package structure may thus be bonded to another element through the bonding structures 210.

Many variations and/or modifications can be made to embodiments of the disclosure. For example, the pattern of the metallic structure 150 may be varied according to the requirements.

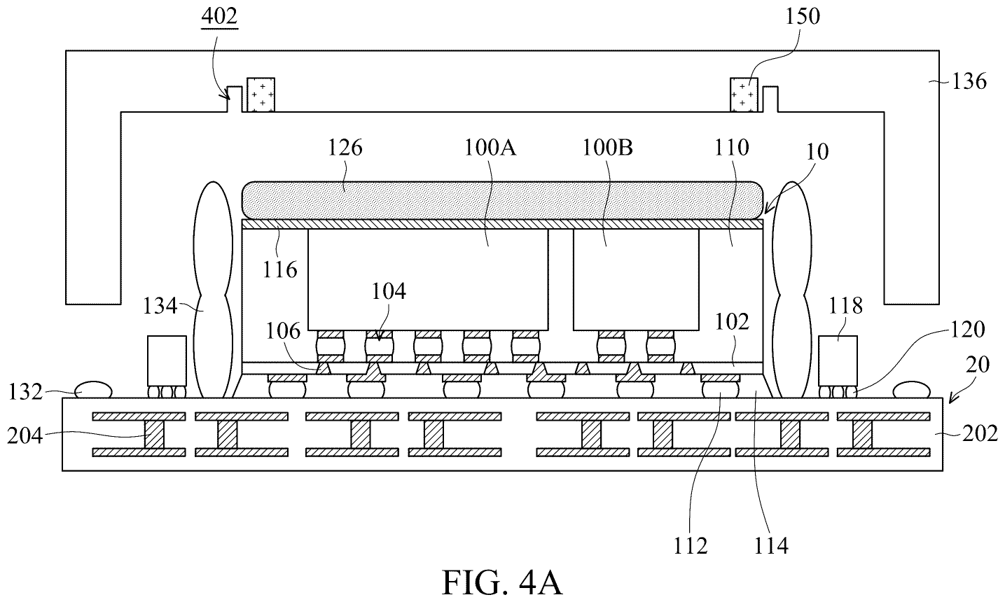

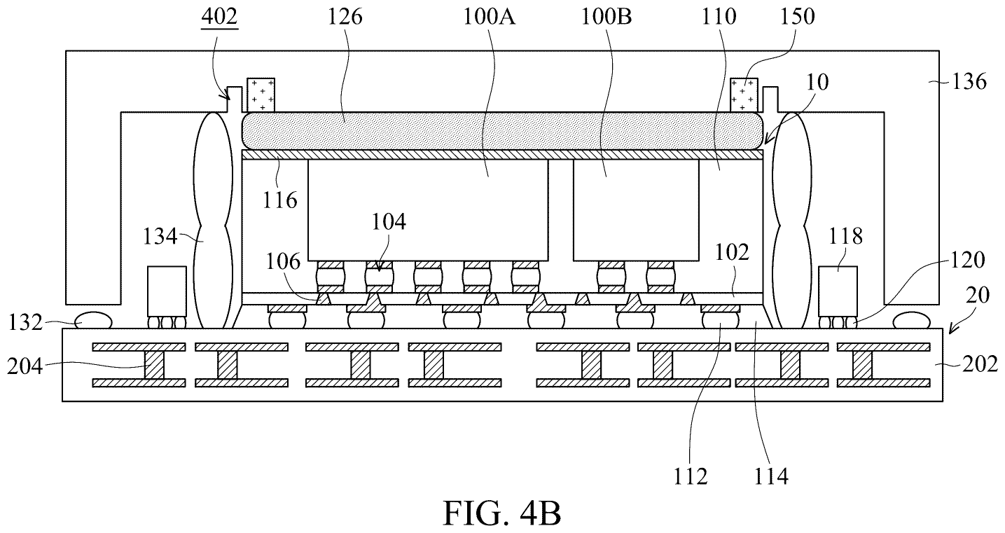

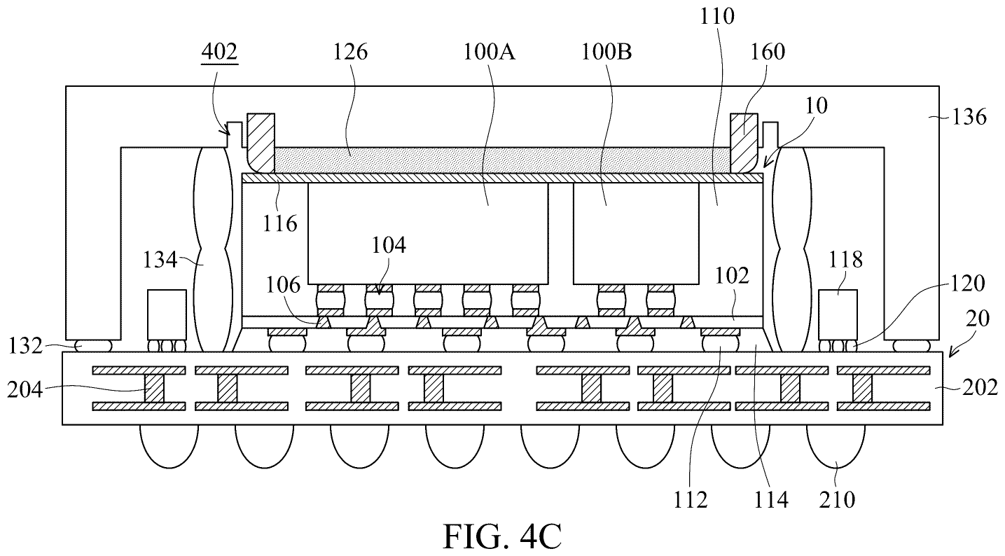

FIGS. 4A-4C are cross-sectional views of various stages of a process for forming a portion of a package structure, in accordance with some embodiments. As shown in FIG. 4A, a structure that is similar to that shown in FIG. 1D is formed. The heat-spreading lid 136 is disposed over the chip package 10 and is ready to be bonded to the substrate 20 and the chip package 10.

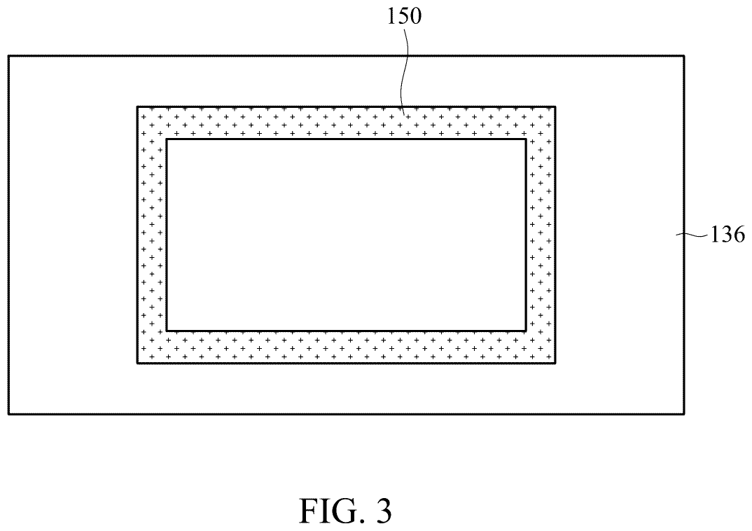

FIG. 3 is a plan view of an intermediate stage of a process for forming a portion of a package structure, in accordance with some embodiments. In some embodiments, FIG. 3 shows the plan view of a portion of the structure shown in FIG. 4A. FIG. 3 shows the plan view of the portion of the heat-spreading lid 136 that is near the metallic structure 150. The trenches 402 are not shown in FIG. 3 for simplicity and clarity. In some embodiments, the metallic structure 150 is a ring structure, as shown in FIG. 3. In some embodiments, the metallic structure 150 extends across the opposite edges of the chip structure 100A and the opposite edges of the chip structure 100B, as shown in FIGS. 3 and 4A

As shown in FIG. 4B, similar to the embodiments illustrated in FIG. 1E, the heat-spreading lid 136 is lowered, in accordance with some embodiments. As a result, the metallic structure 150 is in direct contact with the thermal conductive layer 126. In some embodiments, the heat-spreading lid 136 is also in direct contact with the thermal conductive layer 126. In some embodiments, the heat-spreading lid 136 is in direct contact with the inner adhesive structure 134, as shown in FIG. 4B.

Afterwards, similar to the embodiments illustrated in FIG. 1F, the heat-spreading lid 136 is pressed against the thermal conductive layer 126 and the inner adhesive structure 134 at an elevated temperature, as shown in FIG. 4C in accordance with some embodiments. For example, a heat clamping process is used. In some embodiments, under the thermal compression, the metallic structure 150 and a portion of the thermal conductive layer 126 are transformed into an alloy structure 160, as shown in FIG. 4C. In some embodiments, the alloy structure 160 extends into the heat-spreading lid 136, as shown in FIG. 4C. In some embodiments, the topmost surface of the alloy structure 160 is higher than an interface between the heat-spreading lid 136 and the inner adhesive structure 134. In some embodiments, the topmost surface of the alloy structure 160 is higher than the topmost surface of the remaining portion of the thermal conductive layer 126.

In some embodiments, the metallic structure 150 and the thermal conductive layer 126 are heated for a long period of time to ensure fully reaction between the metallic structure 150 and the portion of the thermal conductive layer 126 that is directly below the metallic structure 150. In some embodiments, the metallic structure 150 and the thermal conductive layer 126 are heated at a temperature around 200 degrees C. for more than 4 hours. As a result, the entirety of the metallic structure 150 and the entirety of the portion of the thermal conductive layer 126 that is directly below the metallic structure 150 are transformed into the alloy structure 160. In some embodiments, the remaining portion of the thermal conductive layer 126 has a higher thermal conductivity than that of the alloy structure 160. In some embodiments, the thermal conductive layer 126 has a lower melting point than the alloy structure 160. In some embodiments, the bonding strength of the alloy structure 160 between the heat-spreading lid 136 and the chip package 10 is greater than that of the remaining portion of the thermal conductive layer 126 between the heat-spreading lid 136 and the chip package 10.

In some embodiments, the alloy structure 160 laterally surrounds the remaining portion of the thermal conductive layer 126. The alloy structure 160 may prevent the remaining portion of the thermal conductive layer 126, located directly above the chip structures 100A and 100B, from flowing away during the heat clamping process. The heat dissipation is improved.

However, embodiments of the disclosure are not limited thereto. Many variations and/or modifications can be made to embodiments of the disclosure. In some other embodiments, the metallic structure 150 and the thermal conductive layer 126 are not heated for a long period of time. As a result, the metallic structure 150 and the portion of the thermal conductive layer 126 directly below the metallic structure 150 are partially transformed into the alloy structure 160.

In some embodiments, a portion of the thermal conductive layer 126 directly above the metallic structure 150 and a portion of the metallic structure 150 are transformed into the alloy structure 160. In some embodiments, the portion of the thermal conductive layer 126 and the portion of the metallic structure 150 that are near the original interface between the thermal conductive layer 126 and the metallic structure 150 are transformed into the alloy structure 160. In some embodiments, the alloy structure 160 is formed between the remaining portion of the thermal conductive layer 126 and the remaining portion of the metallic structure 150. In some other embodiments, a portion of the thermal conductive layer 126 that is directly below the metallic structure 150 and the entirety of the metallic structure 150 together form the alloy structure 160. In some embodiments, the alloy structure 160 is formed between the remaining portion of the thermal conductive layer 126 and the heat-spreading lid 136.

In some embodiments, because the metallic structure 150 and the portion of the thermal conductive layer 126 directly below the metallic structure 150 together form the alloy structure 160, the adhesion between the heat-spreading lid 136 and the chip package 10 is greatly improved. Because the alloy structure 160 laterally surrounding the remaining portion of the thermal conductive layer 126 forms, the thermal conductive layer 126, which could flow during the heat clamping process, may be prevented from flowing away from the chip package 10. Due to good joint between the chip package 10 and the heat-spreading lid 136, heat generated from the chip structures 100A and 100B may thus be led out efficiently through the heat-spreading lid 136. The performance and reliability of the package structure are greatly improved.

Afterwards, similar to the embodiments illustrated in FIG. 1G, multiple bonding structures 210 are formed on the bottom of the substrate 20, as shown in FIG. 4C, in accordance with some embodiments. The bonding structures 210 may include tin-containing solder bumps. The package structure may thus be bonded to another element through the bonding structures 210.

In some embodiments, the metallic structure 150 is a single piece. However, embodiments of the disclosure are not limited thereto. Many variations and/or modifications can be made to embodiments of the disclosure. In some other embodiments, the metallic structure includes multiple metallic island structures that are spaced apart from each other.

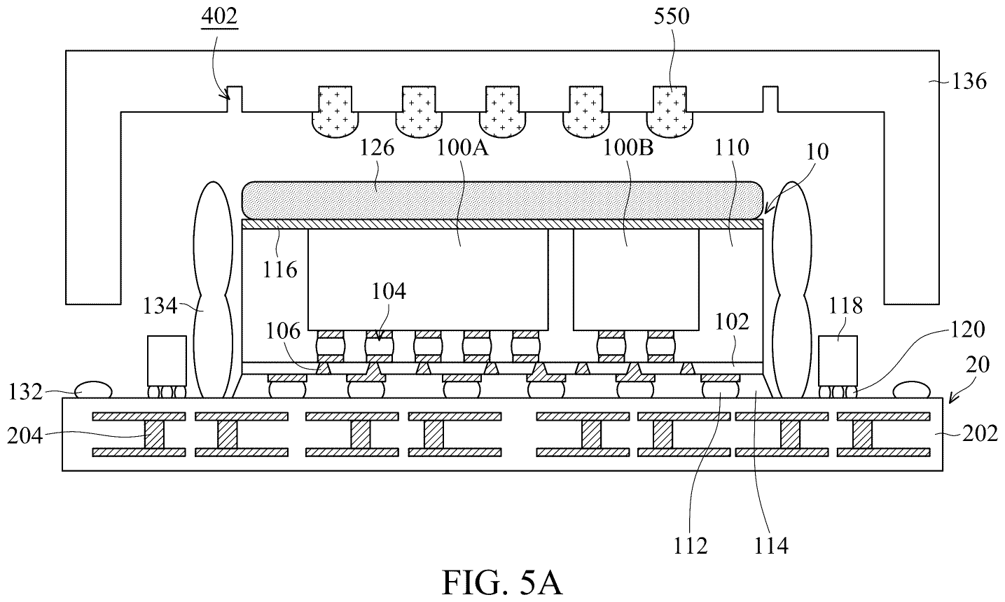

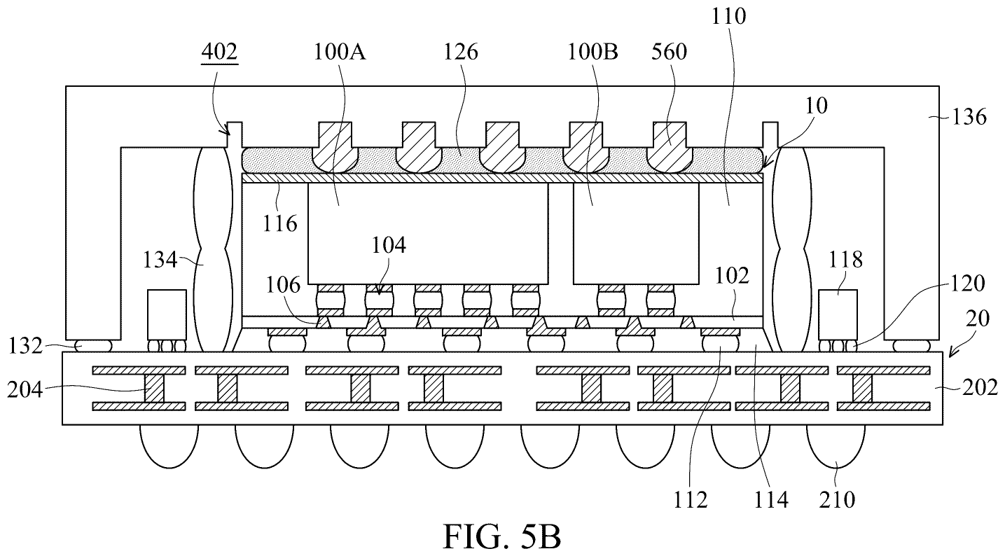

FIGS. 5A-5B are cross-sectional views of various stages of a process for forming a portion of a package structure, in accordance with some embodiments. As shown in FIG. 5A, a structure that is similar to that shown in FIG. 1D is formed. The heat-spreading lid 136 is disposed over the chip package 10 and is ready to be bonded to the substrate 20 and the chip package 10. In some embodiments, there are multiple metallic structures 550 embedded in the heat-spreading lid 136. The metallic structures 550 may be metallic island structures that are spaced apart from each other, as shown in FIG. 5A. In some embodiments, each of the metallic structures 550 has an embedded portion surrounded by the heat-spreading lid 136 and a protruding portion that extends along a surface of the heat-spreading lid 136 that faces the chip package 10. In some embodiments, each of the metallic structures 550 has a convex bottom surface.

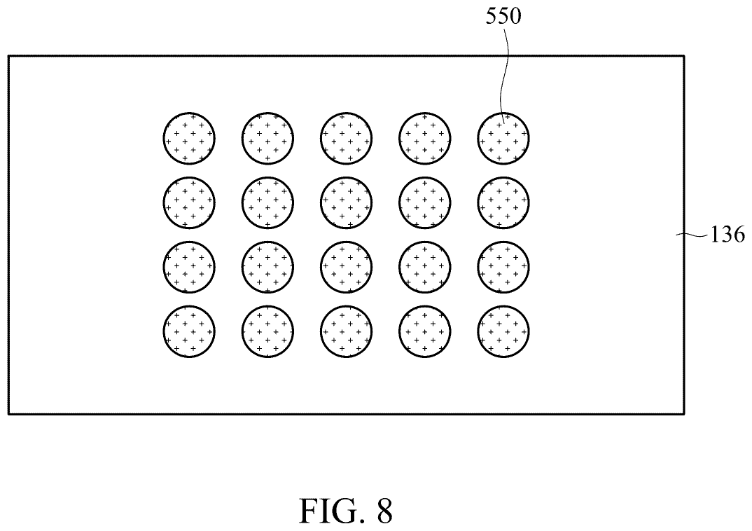

FIG. 8 is a plan view of an intermediate stage of a process for forming a portion of a package structure, in accordance with some embodiments. In some embodiments, FIG. 8 shows the plan view of a portion of the structure shown in FIG. 5A. FIG. 8 shows the plan view of the portion of the heat-spreading lid 136 that is near the metallic structures 550. The trenches 402 are not shown in FIG. 8 for simplicity and clarity. In some embodiments, the metallic structure 150 is a ring structure, as shown in FIG. 3.

Afterwards, similar to the embodiments illustrated in FIGS. 1E-1F, the heat-spreading lid 136 is pressed against the thermal conductive layer 126 and the inner adhesive structure 134 at an elevated temperature, as shown in FIG. 5B in accordance with some embodiments. For example, a heat clamping process is performed. In some embodiments, under the thermal compression, the metallic structures 550 penetrate into the thermal conductive layer 126.

Afterwards, the metallic structures 550 and the portions of the thermal conductive layer 126 near the metallic structures 550 are transformed into multiple alloy structures 560, as shown in FIG. 5B. In some embodiments, the alloy structures 560 extend into the heat-spreading lid 136, as shown in FIG. 5B. In some embodiments, the topmost surfaces of the alloy structures 560 are higher than an interface between the heat-spreading lid 136 and the inner adhesive structure 134. In some embodiments, the topmost surfaces of the alloy structure 560 are higher than the topmost surface of the remaining portion of the thermal conductive layer 126.

In some embodiments, the metallic structure 150 and the thermal conductive layer 126 are heated for a long period of time to ensure that the entirety of the metallic structures 550 are transformed into the alloy structures 560. In some embodiments, the metallic structures 550 and the thermal conductive layer 126 are heated at a temperature around 200 degrees C. for more than 4 hours. As a result, the entirety of the metallic structures 550 are transformed into the alloy structures 560.

In some embodiments, the remaining portion of the thermal conductive layer 126 has a higher thermal conductivity than that of the alloy structures 560. In some embodiments, the bonding strength of the alloy structures 560 between the heat-spreading lid 136 and the chip package 10 is greater than that of the remaining portion of the thermal conductive layer 126 between the heat-spreading lid 136 and the chip package 10.

However, embodiments of the disclosure are not limited thereto. Many variations and/or modifications can be made to embodiments of the disclosure. In some other embodiments, the metallic structures 550 are not heated for a long period of time. As a result, the metallic structures are partially transformed into the alloy structures 560. In some embodiments, one of the alloy structures 560 is thus positioned between the remaining portion of the thermal conductive layer 126 and the remaining portion of one of the metallic structures 550.

In some embodiments, due to the alloy structures 560, the adhesion between the heat-spreading lid 136 and the chip package 10 is greatly improved. Because the alloy structures 560 dispersed within the thermal conductive layer 126 forms, the thermal conductive layer 126, which could flow during the heat clamping process, may be prevented from flowing away from the chip package 10. Due to good joint between the chip package 10 and the heat-spreading lid 136, heat generated from the chip structures 100A and 100B may thus be led out efficiently through the heat-spreading lid 136. The performance and reliability of the package structure are greatly improved.

Afterwards, similar to the embodiments illustrated in FIG. 1G, multiple bonding structures 210 are formed on the bottom of the substrate 20, as shown in FIG. 5B, in accordance with some embodiments. The bonding structures 210 may include tin-containing solder bumps. The package structure may thus be bonded to another element through the bonding structures 210.

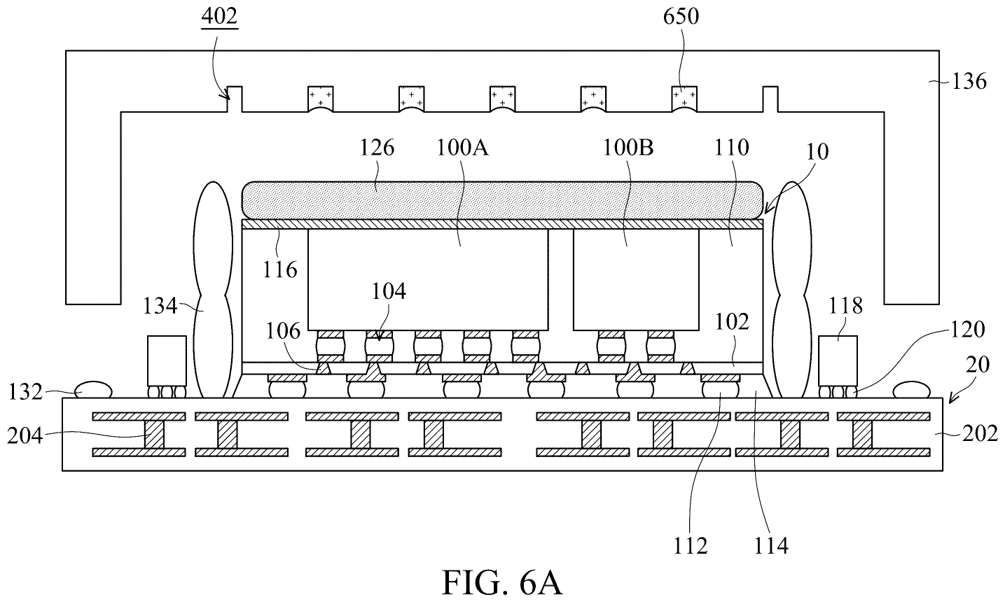

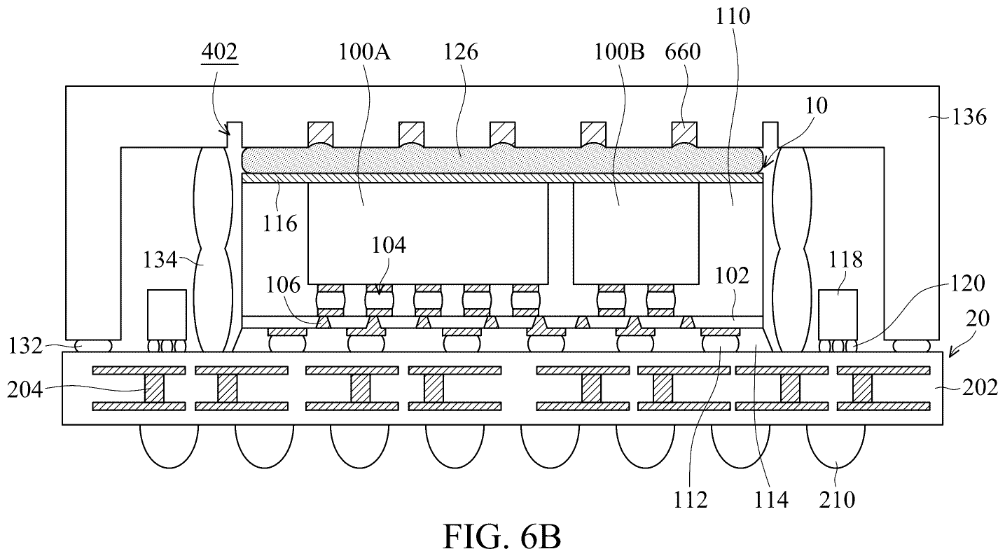

Many variations and/or modifications can be made to embodiments of the disclosure. FIGS. 6A-6B are cross-sectional views of various stages of a process for forming a portion of a package structure, in accordance with some embodiments. As shown in FIG. 6A, a structure that is similar to the structure shown in FIG. 5A is formed. In some embodiments, similar to the embodiments illustrated in FIG. 5A, multiple metallic structures 650 are embedded in the heat-spreading lid 136. In some embodiments, each of the metallic structures 650 has a concave bottom surface. There are multiple recesses formed at the concave bottom surfaces of the metallic structures 650.

Afterwards, similar to the embodiments illustrated in FIGS. 1E-1F, the heat-spreading lid 136 is pressed against the thermal conductive layer 126 and the inner adhesive structure 134 at an elevated temperature, as shown in FIG. 6B in accordance with some embodiments. Portions of the thermal conductive layer 126 may extend into the recesses formed at the concave bottom surfaces of the metallic structures 650 during the heat clamping process. As a result, the metallic structures 650 are in direct contact with the thermal conductive layer 126 after the heat-spreading lid 136 is pressed against the substrate 20. During the heat clamping process, the metallic structures 650 and the portions of the thermal conductive layer 126 near the metallic structures 650 are transformed into multiple alloy structures 660, as shown in FIG. 6B.

In some embodiments, the metallic structures 650 and the thermal conductive layer 126 are heated for a long period of time to ensure that the entirety of the metallic structures 650 are transformed into the alloy structures 660. In some embodiments, the metallic structures 650 and the thermal conductive layer 126 are heated at a temperature around 200 degrees C. for more than 4 hours. As a result, the entirety of the metallic structures 650 are transformed into the alloy structures 660.

However, embodiments of the disclosure are not limited thereto. Many variations and/or modifications can be made to embodiments of the disclosure. In some other embodiments, the metallic structures 650 are not heated for a long period of time. As a result, the metallic structures 650 are partially transformed into the alloy structures 660. In some embodiments, one of the alloy structures 660 is thus positioned between the remaining portion of the thermal conductive layer 126 and the remaining portion of one of the metallic structures 650.

Afterwards, similar to the embodiments illustrated in FIG. 1G, multiple bonding structures 210 are formed on the bottom of the substrate 20, as shown in FIG. 6B, in accordance with some embodiments. The bonding structures 210 may include tin-containing solder bumps. The package structure may thus be bonded to another element through the bonding structures 210.

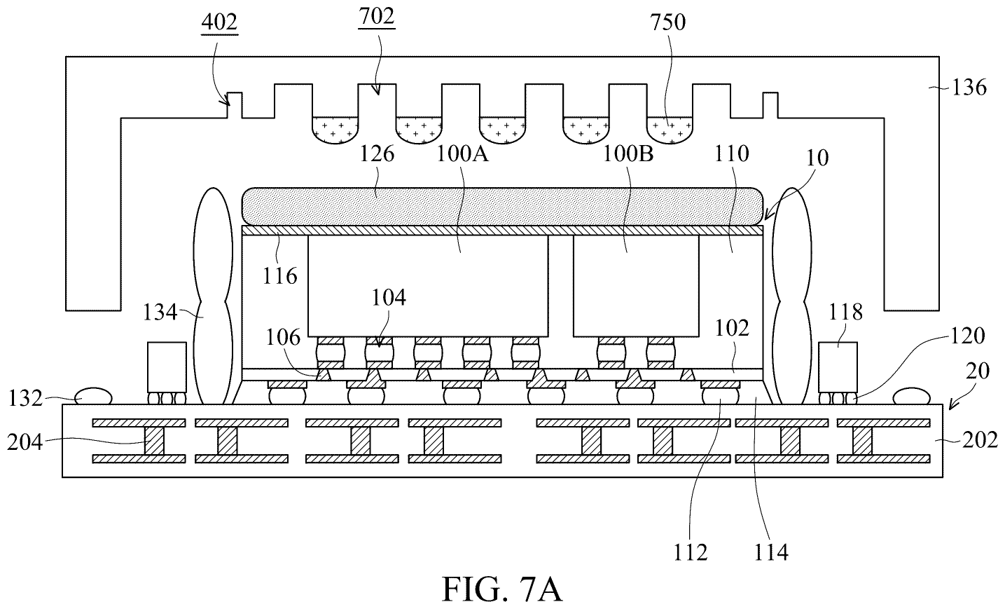

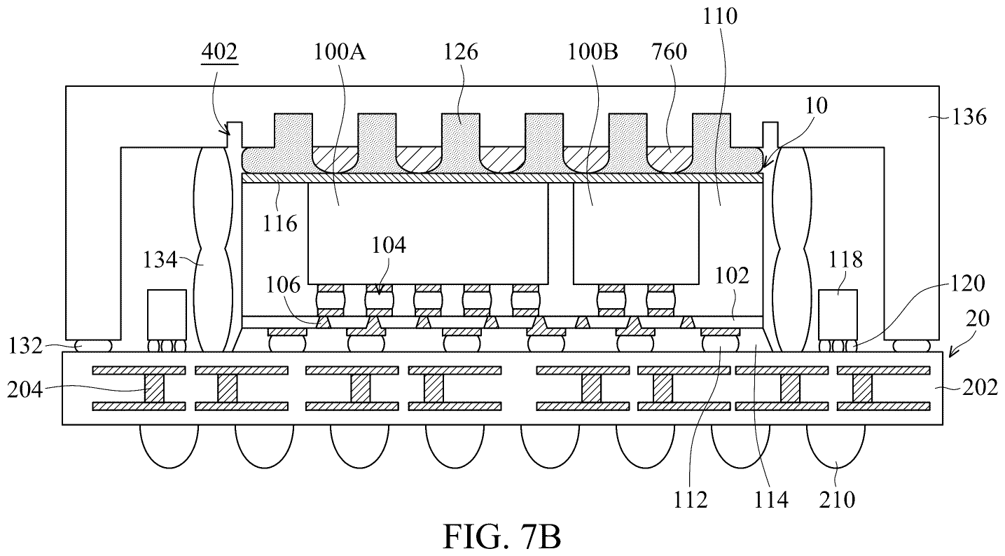

Many variations and/or modifications can be made to embodiments of the disclosure. FIGS. 7A-7B are cross-sectional views of various stages of a process for forming a portion of a package structure, in accordance with some embodiments. As shown in FIG. 7A, a structure that is similar to the structure shown in FIG. 5A is formed. In some embodiments, similar to the embodiments illustrated in FIG. 5A, multiple metallic structures 750 are formed on the heat-spreading lid 136. In some embodiments, each of the metallic structures 750 has a convex bottom surface. There are multiple recesses 702 formed near the metallic structures 750, as shown in FIG. 7A.

Afterwards, similar to the embodiments illustrated in FIGS. 1E-1F, the heat-spreading lid 136 is pressed against the thermal conductive layer 126 and the inner adhesive structure 134 at an elevated temperature, as shown in FIG. 7B in accordance with some embodiments. Portions of the thermal conductive layer 126 may extend upwards into the recesses 702 and laterally surround the metallic structures 750 during the heat clamping process. During the heat clamping process, the metallic structures 750 and the portions of the thermal conductive layer 126 near the metallic structures 750 together form multiple alloy structures 760, as shown in FIG. 7B. In some embodiments, the topmost surface of the alloy structure 760 is vertically between the topmost surface and the bottommost surface of the thermal conductive layer 126, as shown in FIG. 7B.

In some embodiments, the metallic structures 750 and the thermal conductive layer 126 are heated for a long period of time to ensure that the entirety of the metallic structures 750 are transformed into the alloy structures 760. In some embodiments, the metallic structures 750 and the thermal conductive layer 126 are heated at a temperature around 200 degrees C. for more than 4 hours. As a result, the entirety of the metallic structures 750 are transformed into the alloy structures 760.

However, embodiments of the disclosure are not limited thereto. Many variations and/or modifications can be made to embodiments of the disclosure. In some other embodiments, the metallic structures 750 are not heated for a long period of time. As a result, the metallic structures 750 are partially transformed into the alloy structures 760. In some embodiments, one of the alloy structures 760 is thus positioned between the remaining portion of the thermal conductive layer 126 and the remaining portion of one of the metallic structures 750.

Afterwards, similar to the embodiments illustrated in FIG. 1G, multiple bonding structures 210 are formed on the bottom of the substrate 20, as shown in FIG. 6B, in accordance with some embodiments. The bonding structures 210 may include tin-containing solder bumps. The package structure may thus be bonded to another element through the bonding structures 210.

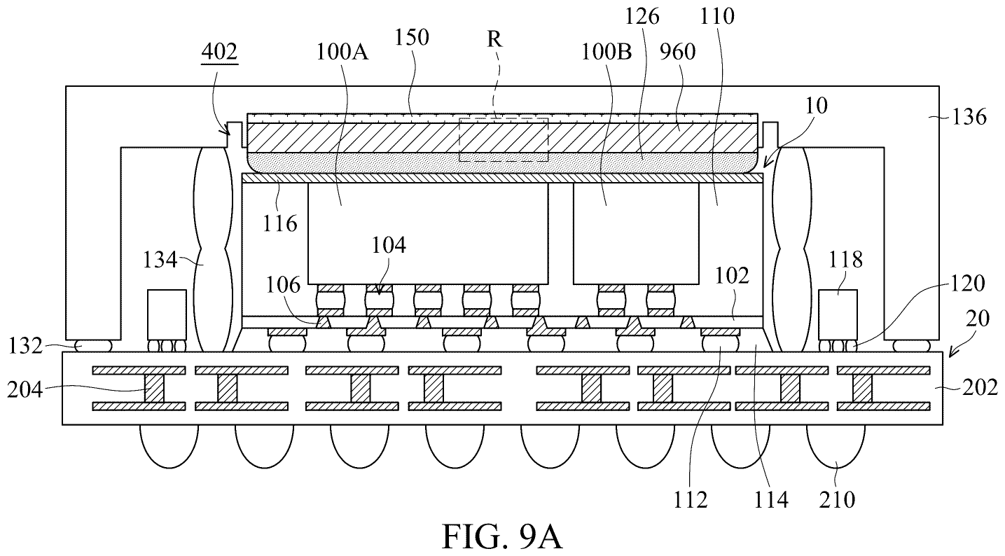

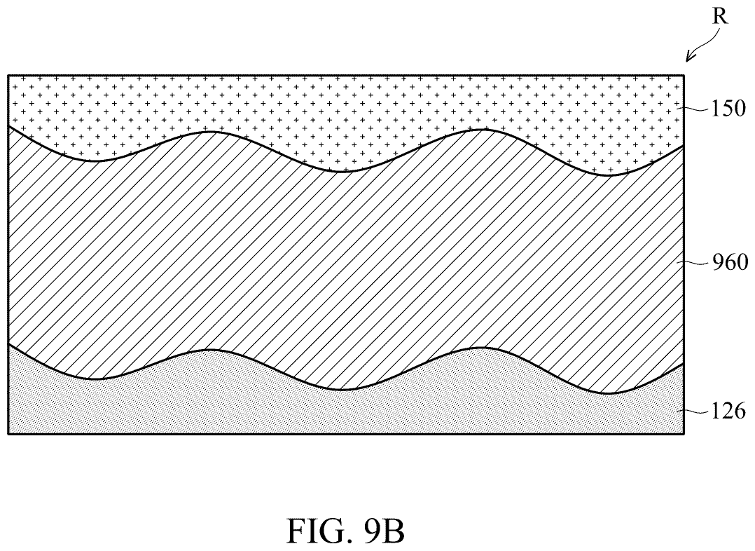

FIG. 9A is a cross-sectional view of a portion of a package structure, in accordance with some embodiments. FIG. 9B is a cross-sectional view of a portion of a package structure, in accordance with some embodiments. In some embodiments, FIG. 9B shows an enlarged cross-sectional view of the portion R of the structure shown in FIG. 9A. In some embodiments, a structure that is similar to the embodiments illustrated in FIG. 1G is formed. In some embodiments, the metallic structure 150 and the thermal conductive layer 126 are partially transformed into an alloy structure 960.

In some embodiments, during the heat clamping process, a lower portion of the metallic structure 150 and an upper portion of the thermal conductive layer 126 react with each other and are together transformed into the alloy structure 960, as shown in FIG. 9A. The alloy structure 960 is positioned between the remaining portion of the metallic structure 150 and the remaining portion of the thermal conductive structure 126.

In some embodiments, the interface between the alloy structure 960 and the thermal conductive layer 126 and the interface between the alloy structure 960 and the metallic structure 150 have uneven profiles, as shown in FIG. 9B. In some embodiments, a lower portion of the alloy structure 960 is positioned below the topmost surface of the thermal conductive layer 126, as shown in FIG. 9B. In some embodiments, an upper portion of the alloy structure 960 is positioned above the bottommost surface of the metallic structure 150, as shown in FIG. 9B.

In some embodiments, one or more metallic structures that have are made of the same material are formed on or embedded in the heat-spreading lid. However, embodiments of the disclosure are not limited thereto. Many variations and/or modifications can be made to embodiments of the disclosure. In some other embodiments, two or more metallic structure that are made of different materials are formed on or embedded in the heat-spreading lid.

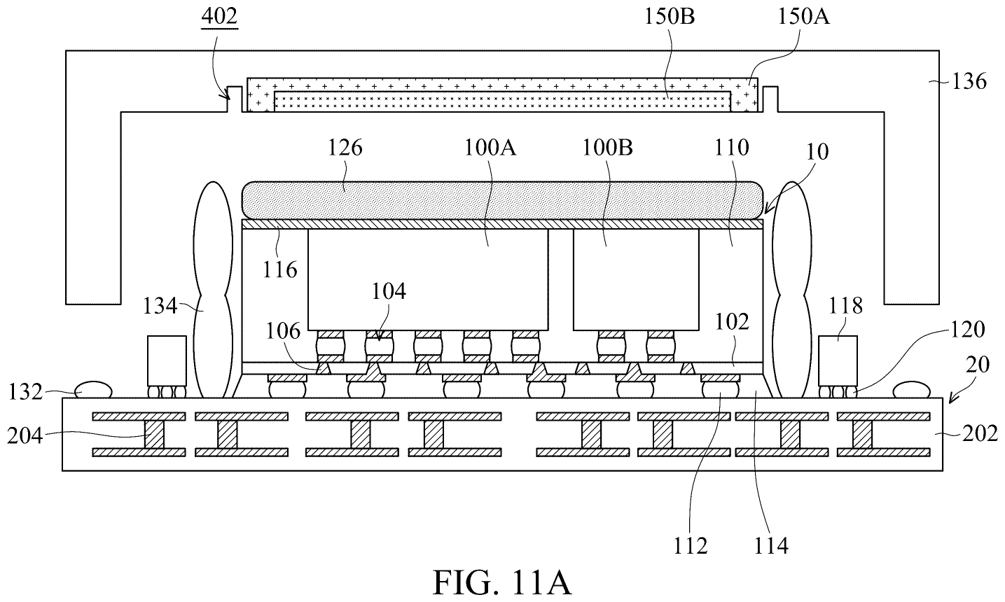

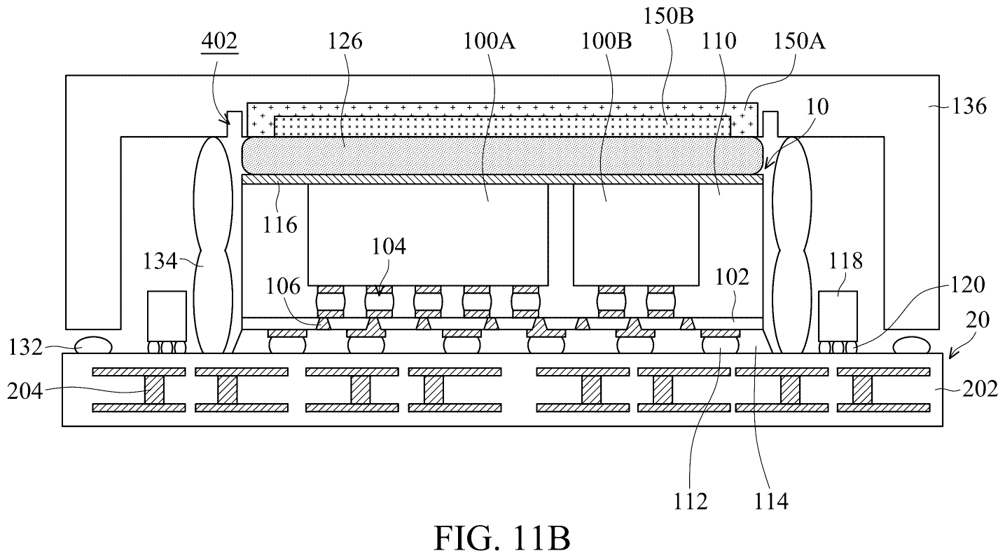

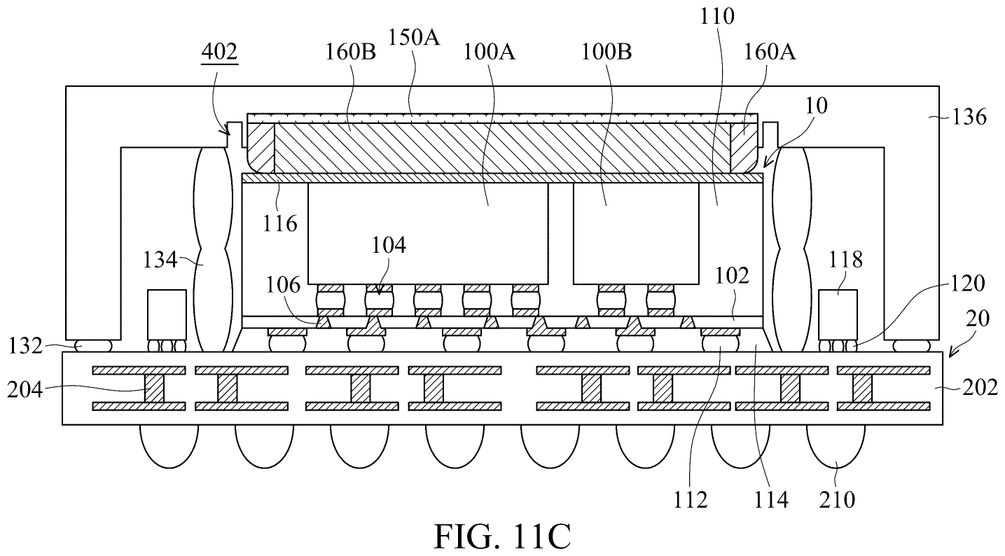

FIGS. 11A-11C are cross-sectional views of various stages of a process for forming a portion of a package structure, in accordance with some embodiments. As shown in FIG. 11A, a structure that is similar to that shown in FIG. 1D is formed. The heat-spreading lid 136 is disposed over the chip package 10 and is ready to be bonded to the substrate 20 and the chip package 10. In some embodiments, multiple metallic structures 150A and 150B are embedded in the heat-spreading lid 136, as shown in FIG. 11A. In some embodiments, the metallic structures 150A and 150B are made of different materials.

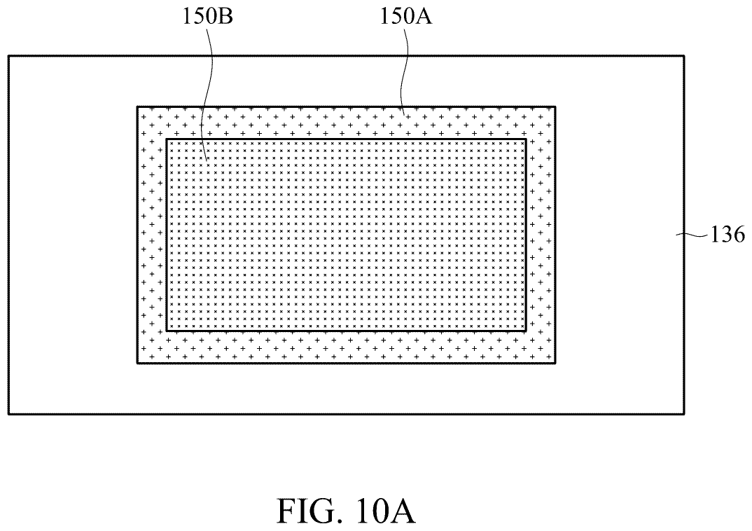

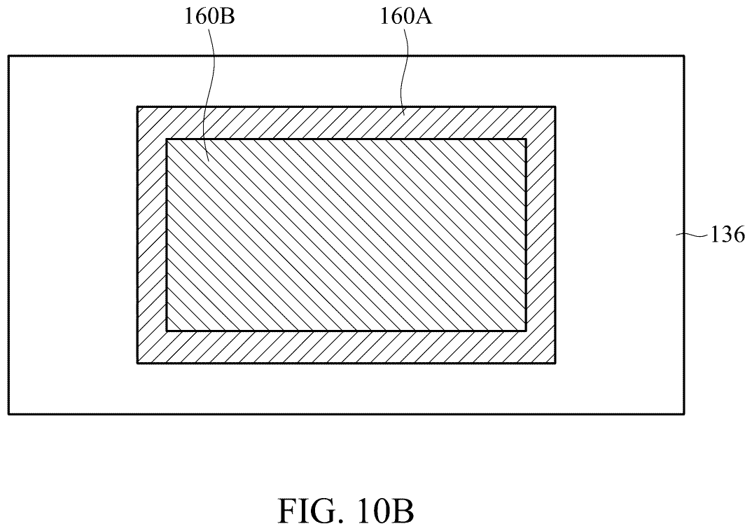

FIGS. 10A-10B are plan views of various stages of a process for forming a portion of a package structure, in accordance with some embodiments. In some embodiments, FIG. 10A shows the plan view of a portion of the structure shown in FIG. 11A. FIG. 10A shows the plan view of the portion of the heat-spreading lid 136 that is near the metallic structures 150A and 150B. The trenches 402 are not shown in FIG. 10A for simplicity and clarity. In some embodiments, the metallic structure 150A includes a ring structure that laterally surrounds the metallic structure 150B, as shown in FIGS. 10A and 11A. In some embodiments, the metallic structures 150A and 150B extend across the opposite edges of the chip structure 100A and the opposite edges of the chip structure 100B, as shown in FIGS. 10A and 11A.

As shown in FIG. 11B, similar to the embodiments illustrated in FIG. 1E, the heat-spreading lid 136 is lowered, in accordance with some embodiments. As a result, the metallic structure 150A is in direct contact with the outer portion of the thermal conductive layer 126. The metallic structure 150B is in direct contact with the inner portion of the thermal conductive layer 126. In some embodiments, the heat-spreading lid 136 is in direct contact with the inner adhesive structure 134, as shown in FIG. 11B.

Afterwards, similar to the embodiments illustrated in FIG. 1F, the heat-spreading lid 136 is pressed against the thermal conductive layer 126 and the inner adhesive structure 134 at an elevated temperature, as shown in FIG. 11C in accordance with some embodiments. For example, a heat clamping process is performed. In some embodiments, under the thermal compression, a portion of the metallic structure 150A and a portion of the thermal conductive layer 126 are transformed into an alloy structure 160A, as shown in FIGS. 10B and 11C. In some embodiments, a portion of the metallic structure 150B and a portion of the thermal conductive layer 126 are transformed into an alloy structure 160B.

In some embodiments, the alloy structure 160A laterally surrounds the alloy structure 160B, as shown in FIG. 10B. In some embodiments, the alloy structure 160B has a higher thermal conductivity than that of the alloy structure 160A. In some embodiments, the bonding strength of the alloy structure 160A between the heat-spreading lid 136 and the chip package 10 is greater than that of the alloy structure 160B between the heat-spreading lid 136 and the chip package 10.

In some embodiments, the transformation of the alloy structure 160A is faster than the transformation of the alloy structure 160B. For example, the alloy structure 160 may contain indium and zinc. The alloy structure 160A that is formed faster than the alloy structure 160B may laterally surround and prevent the thermal conductive layer 126, located directly under the metallic structure 150B, from flowing away during the heat clamping process. Therefore, there is sufficient reaction time for the metallic structure 150B and the thermal conductive layer 126 underneath. As a result, the alloy structure 160B is formed.

Afterwards, similar to the embodiments illustrated in FIG. 1G, multiple bonding structures 210 are formed on the bottom of the substrate 20, as shown in FIG. 11C, in accordance with some embodiments. The bonding structures 210 may include tin-containing solder bumps. The package structure may thus be bonded to another element through the bonding structures 210.

Many variations and/or modifications can be made to embodiments of the disclosure. The pattern of the metallic structure embedded in or formed on the heat-spreading lid may be varied and/or designed according to the types of the chip structures thereunder.

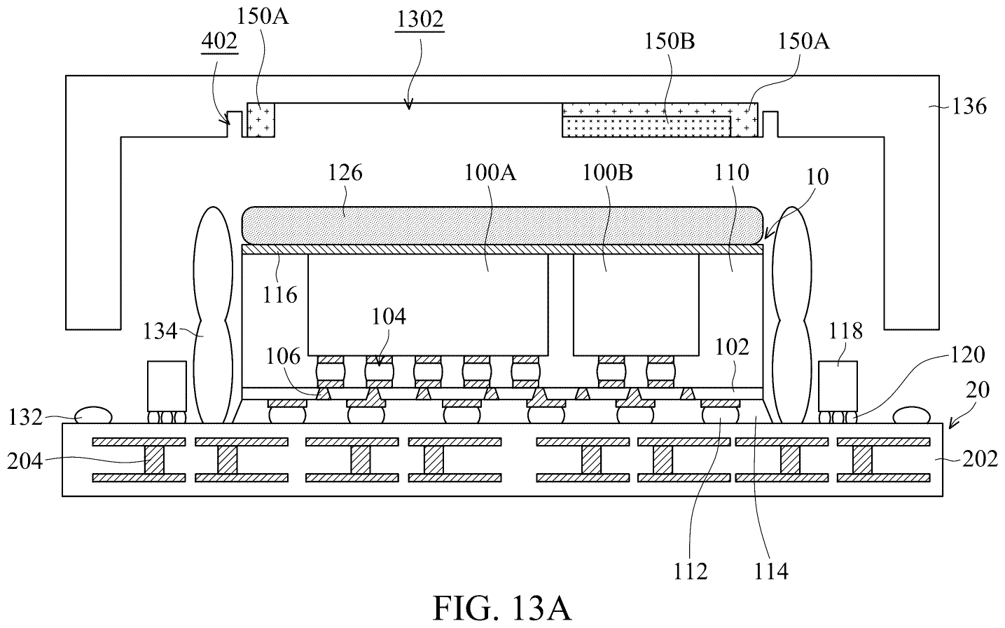

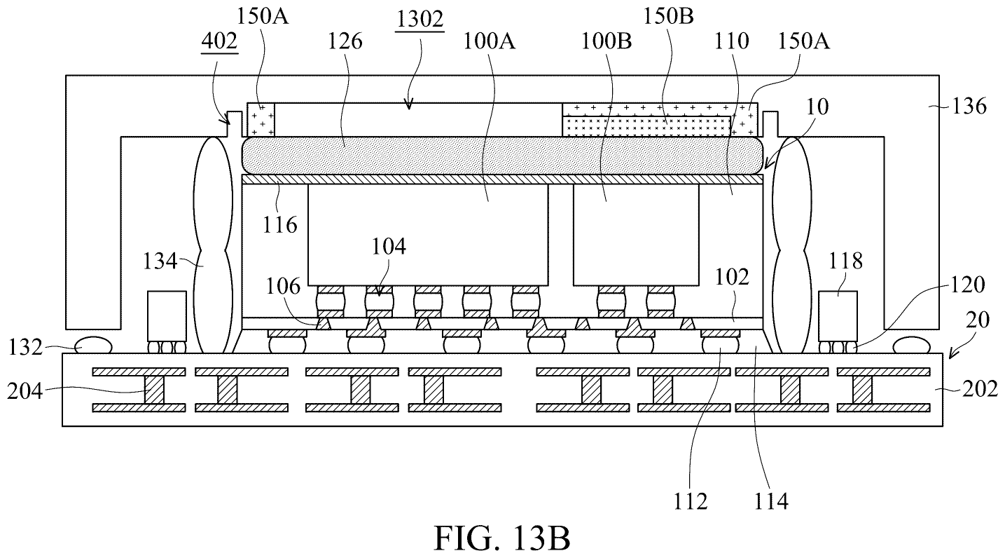

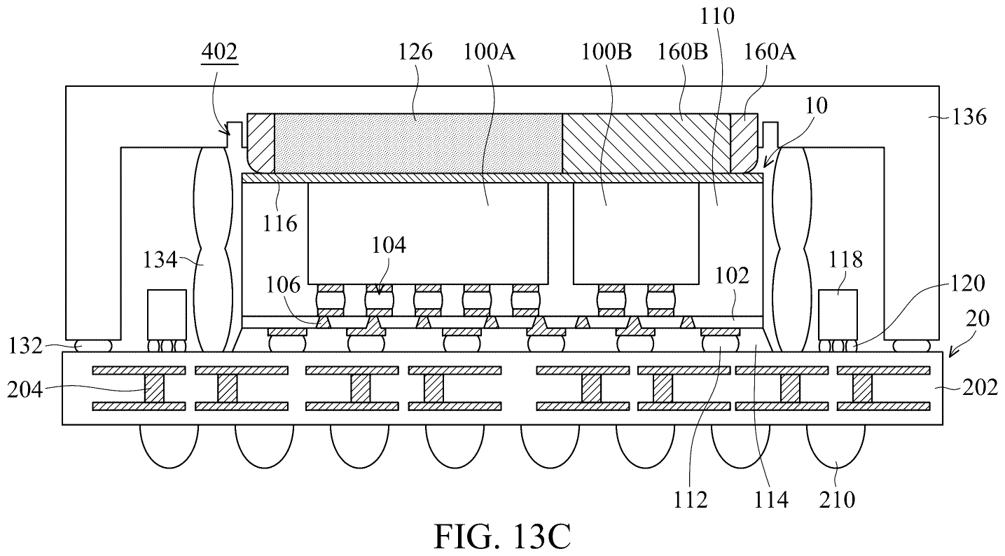

FIGS. 13A-13C are cross-sectional views of various stages of a process for forming a portion of a package structure, in accordance with some embodiments. As shown in FIG. 13A, a structure that is similar to that shown in FIG. 11A is formed. The heat-spreading lid 136 is disposed over the chip package 10 and is ready to be bonded to the substrate 20 and the chip package 10. In some embodiments, multiple metallic structures 150A and 150B are embedded in the heat-spreading lid 136, as shown in FIG. 13A. In some embodiments, the metallic structures 150A and 150B are made of different materials. In some embodiments, the metallic structures 150A and 150B are partially removed to form a recess 1302 that exposes the heat-spreading lid 136.

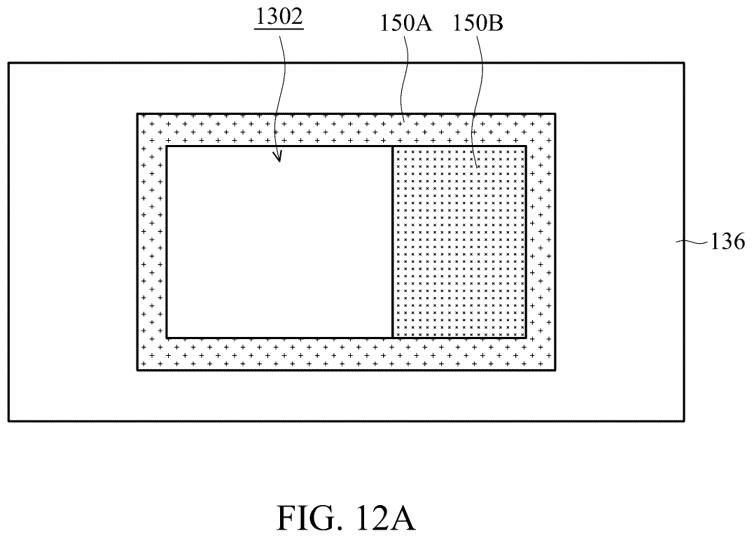

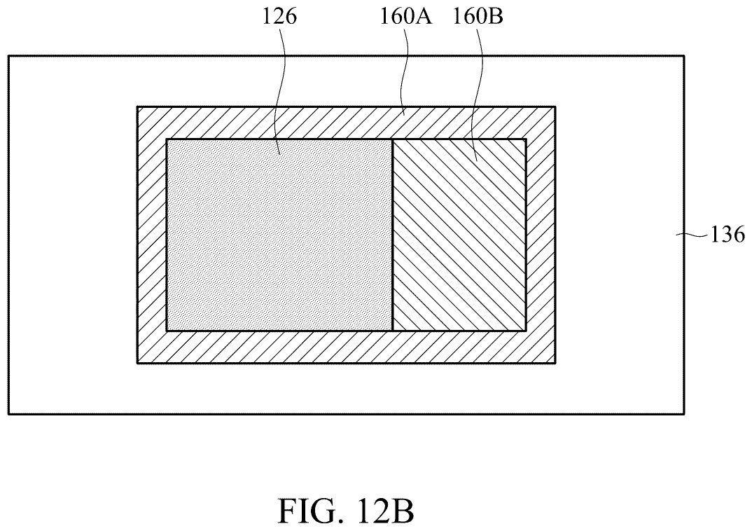

FIGS. 12A-12B are plan views of various stages of a process for forming a portion of a package structure, in accordance with some embodiments. In some embodiments, FIG. 12A shows the plan view of a portion of the structure shown in FIG. 13A. FIG. 12A shows the plan view of the portion of the heat-spreading lid 136 that is near the metallic structures 150A and 150B and the recess 1302. The trenches 402 are not shown in FIG. 12A for simplicity and clarity. In some embodiments, the metallic structure 150A includes a ring structure that laterally surrounds the metallic structure 150B, as shown in FIGS. 12A and 13A. In some embodiments, the metallic structure 150A extend across the opposite edges of the chip structure 100A and the opposite edges of the chip structure 100B, as shown in FIGS. 12A and 13A. In some embodiments, the metallic structure 150B extend across the opposite edges of the chip structure 100B, as shown in FIGS. 12A and 13A.

As shown in FIG. 13B, similar to the embodiments illustrated in FIG. 11B, the heat-spreading lid 136 is lowered, in accordance with some embodiments. As a result, the metallic structure 150A is in direct contact with the outer portion of the thermal conductive layer 126. The metallic structure 150B is in direct contact with the portion of the thermal conductive layer 126 that is directly above the chip structure 100B. In some embodiments, the heat-spreading lid 136 is in direct contact with the inner adhesive structure 134, as shown in FIG. 13B.

Afterwards, similar to the embodiments illustrated in FIG. 11C, the heat-spreading lid 136 is pressed against the thermal conductive layer 126 and the inner adhesive structure 134 at an elevated temperature, as shown in FIG. 13C in accordance with some embodiments. For example, a heat clamping process is performed. In some embodiments, under the thermal compression, a portion of the metallic structure 150A and a portion of the thermal conductive layer 126 are transformed into an alloy structure 160A, as shown in FIGS. 12B and 13C. In some embodiments, the metallic structure 150B and the portion of the thermal conductive layer 126 that is directly above the chip structure 100B are transformed into an alloy structure 160B.

In some embodiments, during the heat clamping process, the remaining portion of the thermal conductive layer 126 that is not transformed into the alloy structures 160A and 160B extends upwards to fill the recess 1302. In some embodiments, the thermal conductive layer 126 is in direct contact with the heat-spreading lid 136. In some embodiments, the thermal conductive layer 126 extends across opposite edges of the chip structure 100A.

In some embodiments, the alloy structure 160A laterally surrounds the alloy structure 160B and the remaining portion of the thermal conductive layer 126, as shown in FIG. 12B. The alloy structure 160A surrounds one or more corners of the thermal conductive layer 126. In some embodiments, the thermal conductive layer 126 has a higher thermal conductivity than that of the alloy structure 160B. In some embodiments, the alloy structure 160B has a higher thermal conductivity than that of the alloy structure 160A. In some embodiments, the bonding strength of the alloy structure 160B between the heat-spreading lid 136 and the chip package 10 is greater than that of the thermal conductive layer 126 between the heat-spreading lid 136 and the chip package 10. In some embodiments, the bonding strength of the alloy structure 160A between the heat-spreading lid 136 and the chip package 10 is greater than that of the alloy structure 160B between the heat-spreading lid 136 and the chip package 10.

The thermal conductive layer 126 directly above the chip structure 100A may help to improve the heat dissipation of the chip structure 100A (such as a logic chip structure) that generates more heat than the chip structure 100B (such as a memory chip structure) during operation. The alloy structure 160B directly above the chip structure 100B may provide sufficient heat dissipation to the chip structure 100B that generates less heat than the chip structure 100A during operation. The alloy structure 160B together with the alloy structure 160A may further improve adhesion between the heat-spreading lid 136 and the chip package 10. The heat dissipation of the chip package 10 is thus greatly improved. The performance and reliability of the package structure are significantly improved.

In some embodiments, the transformation of the alloy structure 160A is faster than the transformation of the alloy structure 160B. For example, the alloy structure 160 may contain indium and zinc. The alloy structure 160A that is formed faster than the alloy structure 160B may laterally surround and prevent the thermal conductive layer 126, located directly under the metallic structure 150B or located directly under the recess 1302, from flowing away during the heat clamping process. Therefore, there is sufficient reaction time for the metallic structure 150B and the thermal conductive layer 126 underneath. As a result, the alloy structure 160B is formed.

Afterwards, similar to the embodiments illustrated in FIG. 11C, multiple bonding structures 210 are formed on the bottom of the substrate 20, as shown in FIG. 13C, in accordance with some embodiments. The bonding structures 210 may include tin-containing solder bumps. The package structure may thus be bonded to another element through the bonding structures 210.

Many variations and/or modifications can be made to embodiments of the disclosure. The pattern of the metallic structure embedded in or formed on the heat-spreading lid may be varied and/or designed according to the types of the chip structures thereunder.

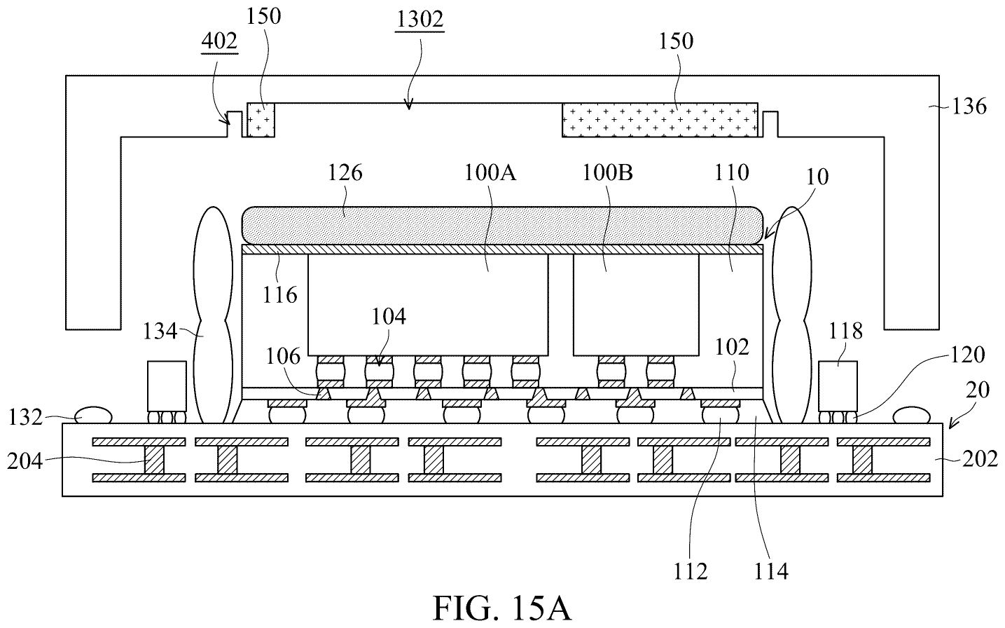

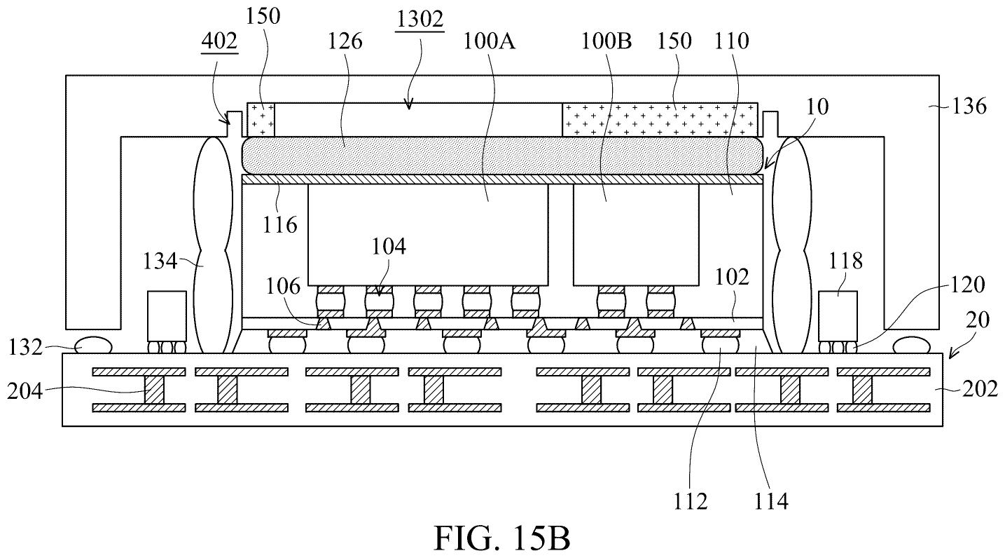

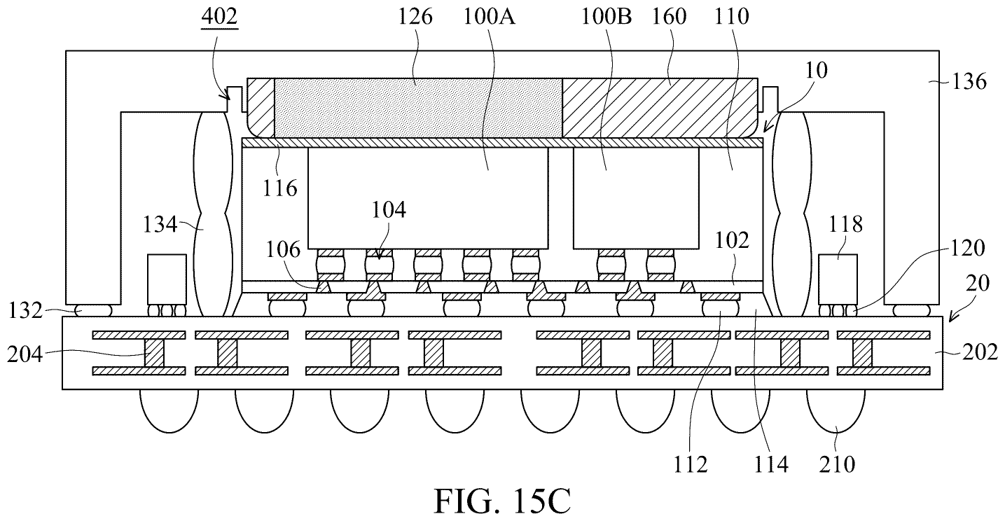

FIGS. 15A-15C are cross-sectional views of various stages of a process for forming a portion of a package structure, in accordance with some embodiments. As shown in FIG. 15A, a structure that is similar to that shown in FIG. 13A is formed. The heat-spreading lid 136 is disposed over the chip package 10 and is ready to be bonded to the substrate 20 and the chip package 10. In some embodiments, the metallic structure 150 embedded in the heat-spreading lid 136, as shown in FIG. 15A. In some embodiments, the metallic structure 150 extends across the opposite edges of the chip structure 100B. In some embodiments, the metallic structure 150 is partially removed to form a recess 1302 that exposes the heat-spreading lid 136.

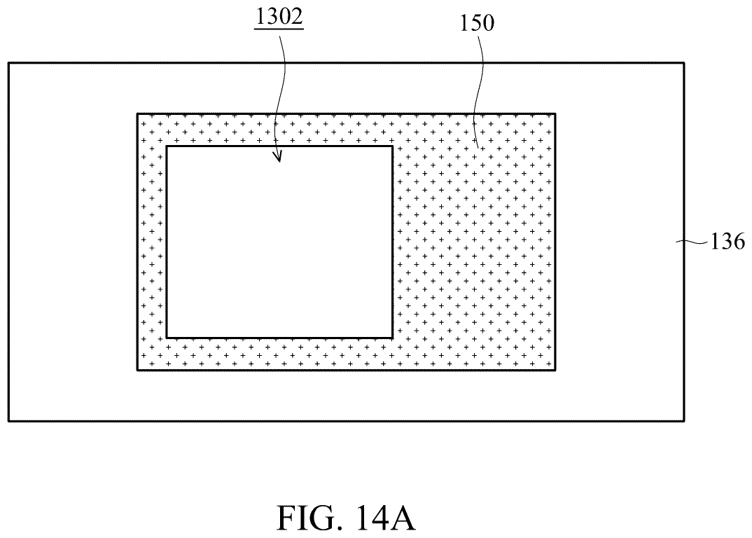

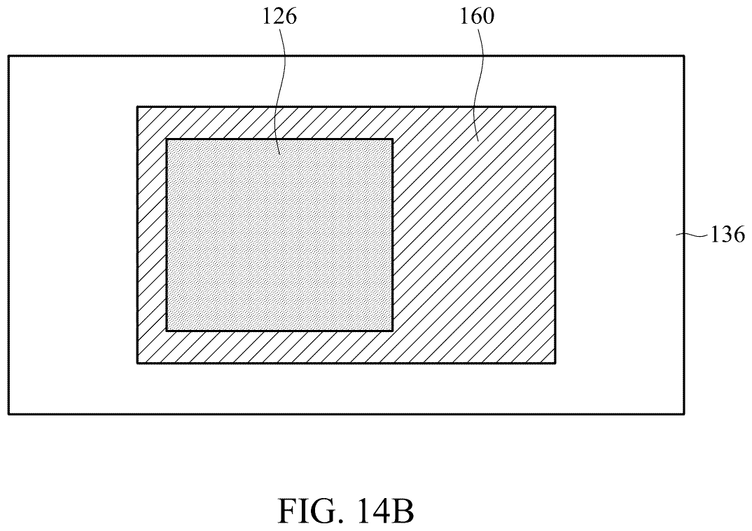

FIGS. 14A-14B are plan views of various stages of a process for forming a portion of a package structure, in accordance with some embodiments. In some embodiments, FIG. 14A shows the plan view of a portion of the structure shown in FIG. 15A. FIG. 14A shows the plan view of the portion of the heat-spreading lid 136 that is near the metallic structure 150 and the recess 1302. The trenches 402 are not shown in FIG. 14A for simplicity and clarity. In some embodiments, the metallic structure includes a ring structure that laterally surrounds the recess 1302, as shown in FIGS. 14A and 15A.

As shown in FIG. 15B, similar to the embodiments illustrated in FIG. 13B, the heat-spreading lid 136 is lowered, in accordance with some embodiments. As a result, the metallic structure 150 is in direct contact with the outer portion of the thermal conductive layer 126 and the portion of the thermal conductive layer 126 that is directly above the chip structure 100B. In some embodiments, the heat-spreading lid 136 is in direct contact with the inner adhesive structure 134, as shown in FIG. 15B.

Afterwards, similar to the embodiments illustrated in FIG. 13C, the heat-spreading lid 136 is pressed against the thermal conductive layer 126 and the inner adhesive structure 134 at an elevated temperature, as shown in FIG. 15C in accordance with some embodiments. For example, a heat clamping process is performed. In some embodiments, under the thermal compression, all or part of the metallic structure 150 and a portion of the thermal conductive layer 126 are transformed into an alloy structure 160, as shown in FIGS. 14B and 15C.

In some embodiments, during the heat clamping process, the remaining portion of the thermal conductive layer 126 that is not transformed into the alloy structure 160 extends upwards to fill the recess 1302. In some embodiments, the thermal conductive layer 126 is in direct contact with the heat-spreading lid 136. In some embodiments, the thermal conductive layer 126 extends across opposite edges of the chip structure 100A.

In some embodiments, the alloy structure 160 laterally surrounds the remaining portion of the thermal conductive layer 126, as shown in FIGS. 14B and 15C. In some embodiments, the thermal conductive layer 126 has a higher thermal conductivity than that of the alloy structure 160. In some embodiments, the bonding strength of the alloy structure 160 between the heat-spreading lid 136 and the chip package 10 is greater than that of the thermal conductive layer 126 between the heat-spreading lid 136 and the chip package 10.

The thermal conductive layer 126 directly above the chip structure 100A may help to improve the heat dissipation of the chip structure 100A that generates more heat than the chip structure 100B during operation. The alloy structure 160 directly above the chip structure 100B may provide sufficient heat dissipation to the chip structure 100B that generates less heat than the chip structure 100A during operation. The alloy structure 160 may further improve adhesion between the heat-spreading lid 136 and the chip package 10. The heat dissipation of the chip package 10 is thus greatly improved. The performance and reliability of the package structure are significantly improved.

Afterwards, similar to the embodiments illustrated in FIG. 13C, multiple bonding structures 210 are formed on the bottom of the substrate 20, as shown in FIG. 15C, in accordance with some embodiments. The bonding structures 210 may include tin-containing solder bumps. The package structure may thus be bonded to another element through the bonding structures 210.

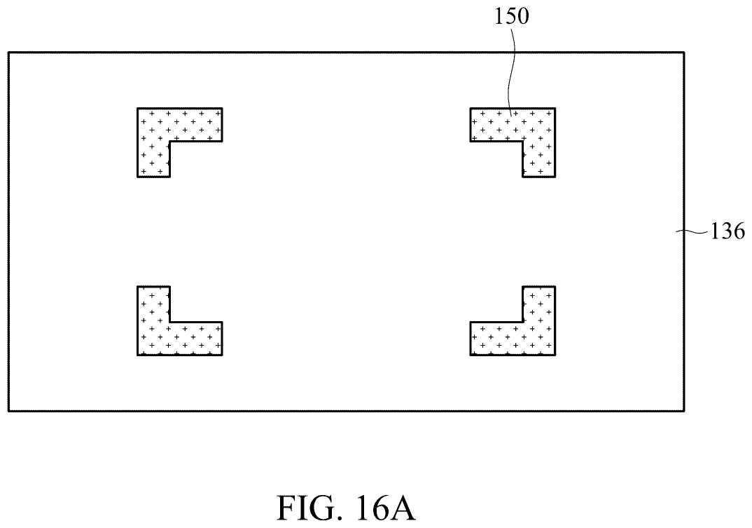

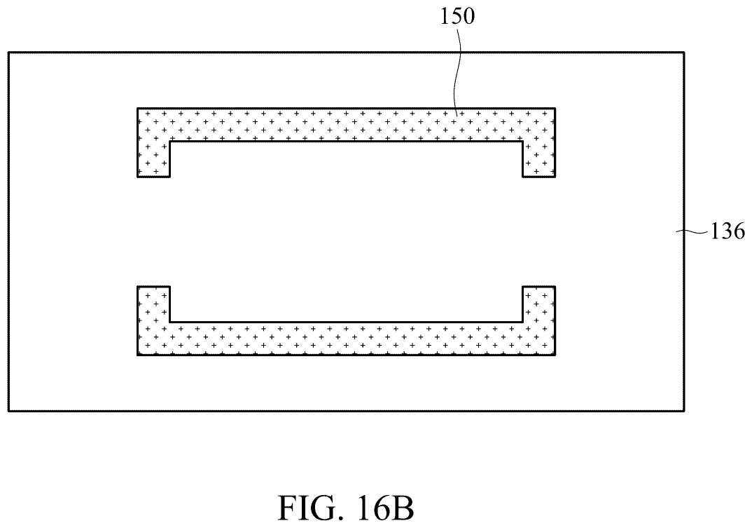

Many variations and/or modifications can be made to embodiments of the disclosure. The pattern of the metallic structure may have many variations. FIG. 16A is a plan view of an intermediate stage of a process for forming a portion of a package structure, in accordance with some embodiments. In some embodiments, multiple metallic structures 150 are embedded in or formed on the heat-spreading lid 136. In some embodiments, the metallic structures 150 are positioned above the corner portions of the chip structure 10 thereunder.

Many variations and/or modifications can be made to embodiments of the disclosure. The pattern of the metallic structure may have many variations. FIG. 16B is a plan view of an intermediate stage of a process for forming a portion of a package structure, in accordance with some embodiments. In some embodiments, multiple metallic structures 150 are embedded in or formed on the heat-spreading lid 136. In some embodiments, the metallic structures 150 covers the corner portions of the chip package 10 thereunder and extend across multiple edges of the chip structures formed in the chip package 10 thereunder.

Embodiments of the disclosure form a package structure with a heat-spreading lid. A thermal conductive structure is formed between the heat-spreading lid and the chip structures within the package structure. A metallic structure with the designed pattern is embedded in or formed on the heat-spreading lid and faces a thermal conductive layer that is formed on the chip structures. During a heat clamping process for bonding the heat-spreading lid to the chip structures, the metallic structure and the thermal conductive layer are partially or completely transformed into an alloy structure (or an intermetallic compound structure) that improves the adhesion between the heat-spreading lid and the chip structures. Because the alloy structure forms, the thermal conductive layer, which could flow during the heat clamping process, may be prevented from flowing away from the chip structures. As a result, heat generated from the chip structures may thus be led out efficiently through the heat-spreading lid. The performance and reliability of the package structure are greatly improved.

In accordance with some embodiments, a method for forming a package structure is provided. The method includes disposing a chip-containing structure over a substrate and forming a thermal conductive layer over the chip-containing structure. The method also includes disposing a heat-spreading lid over the chip-containing structure and the thermal conductive layer. A metallic structure is embedded in the heat-spreading lid, and the metallic structure faces the thermal conductive layer. The method further includes pressing the heat-spreading lid against the chip-containing structure at an elevated temperature such that a portion of or an entirety of the metallic structure and a portion of or an entirety of the thermal conductive layer are transformed into an intermetallic compound material.

In accordance with some embodiments, a method for forming a package structure is provided. The method includes disposing a logic chip structure and a memory chip structure over a substrate and forming a metal adhesive layer over the logic chip structure and the memory chip structure. The method also includes forming an indium layer over the metal adhesive layer and disposing a heat-spreading lid on the indium layer. A patterned metallic structure is embedded in the heat-spreading lid and is in direct contact with the indium layer. The method further includes pressing the heat-spreading lid and the substrate against each other at an elevated temperature. As a result, a portion of or an entirety of the patterned metallic structure and a portion of or an entirety of the indium layer together form an indium-containing alloy.

In accordance with some embodiments, a package structure is provided. The package structure includes a substrate and a heat-spreading lid over the substrate. The package structure also includes a chip-containing structure between the substrate and the heat-spreading lid. The package structure further includes a thermal conductive structure between the chip-containing structure and the heat-spreading lid. The thermal conductive layer includes an intermetallic compound material containing first metallic elements and second metallic elements. The intermetallic compound material extends into the heat-spreading lid.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
disposing a chip-containing structure over a substrate;
forming a thermal conductive layer over the chip-containing structure;
disposing a heat-spreading lid over the chip-containing structure and the thermal conductive layer, wherein a metallic structure is embedded in the heat-spreading lid, and the metallic structure faces the thermal conductive layer; and
pressing the heat-spreading lid against the chip-containing structure at an elevated temperature such that at least a portion of the metallic structure and at least a portion of the thermal conductive layer are transformed into an intermetallic compound material.

2. The method for forming a package structure as claimed in claim 1, wherein the metallic structure comprises gold, silver, tin, zinc, or a combination thereof.

3. The method for forming a package structure as claimed in claim 1, wherein the metallic structure extends across opposite edges of the chip-containing structure.

4. The method for forming a package structure as claimed in claim 1, wherein a second metallic structure is embedded in the heat-spreading lid, and at least a portion of the second metallic structure and a second portion of the thermal conductive layer are transformed into a second intermetallic compound material after pressing the heat-spreading lid against the chip-containing structure at the elevated temperature.

5. The method for forming a package structure as claimed in claim 1, further comprising:
disposing a second chip-containing structure over the substrate, wherein the chip-containing structure generates more heat than the second chip-containing structure during operation;
forming a protective layer laterally surrounding the chip-containing structure and the second chip-containing structure; and
forming the thermal conductive layer over the protective layer, the chip-containing structure and the second chip-containing structure.

6. The method for forming a package structure as claimed in claim 5, wherein a second metallic structure is embedded in the heat-spreading lid, the second metallic structure faces the thermal conductive layer, the second metallic structure extends across opposite edges of the second chip-containing structure, the metallic structure and the second metallic structure are made of different materials, and the metallic structure laterally surrounds the second metallic structure.

7. The method for forming a package structure as claimed in claim 6, wherein at least a portion of the second metallic structure and a second portion of the thermal conductive layer are transformed into a second intermetallic compound material while pressing the heat-spreading lid against the chip-containing structure at the elevated temperature.

8. The method for forming a package structure as claimed in claim 7, wherein the transformation of the intermetallic compound material is faster than the transformation of the second intermetallic compound material.

9. The method for forming a package structure as claimed in claim 5, wherein the metallic structure extends across opposite edges of the second chip-containing structure, the metallic structure surrounds a recess directly above the chip-containing structure, the thermal conductive layer extends into the recess after pressing the heat-spreading lid against the chip-containing structure, and the intermetallic compound material laterally surrounds the thermal conductive layer that extends into the recess.

10. The method for forming a package structure as claimed in claim 1, wherein the intermetallic compound material is formed between a remaining portion of the metallic structure and a remaining portion of the thermal conductive layer.

11. A method for forming a package structure, comprising:
disposing a logic chip structure and a memory chip structure over a substrate;
forming a metal adhesive layer over the logic chip structure and the memory chip structure;
forming an indium layer over the metal adhesive layer;
disposing a heat-spreading lid on the indium layer, wherein a patterned metallic structure is embedded in the heat-spreading lid and is in direct contact with the indium layer; and
pressing the heat-spreading lid and the substrate against each other at an elevated temperature such that at least a portion of the patterned metallic structure and at least a portion of the indium layer together form an indium-containing alloy.

12. The method for forming a package structure as claimed in claim 11, wherein:
the patterned metallic structure comprises a plurality of metallic island structures,
while pressing the heat-spreading lid and the substrate against each other at the elevated temperature, the metallic island structures penetrate into the indium layer, and
the metallic island structures are transformed into portions of the indium-containing alloy.

13. The method for forming a package structure as claimed in claim 12, wherein a topmost surface of the indium-containing alloy is vertically between a topmost surface of the indium layer and a bottommost surface of the indium layer.

14. The method for forming a package structure as claimed in claim 11, wherein the indium-containing alloy extends across opposite edges of the memory chip structure, and a remaining portion of the indium layer extends across opposite edges of the logic chip structure.

15. The method for forming a package structure as claimed in claim 14, wherein the indium-containing alloy laterally surrounds the remaining portion of the indium layer.

16. A package structure, comprising:
a substrate;
a heat-spreading lid over the substrate;
a chip-containing structure between the substrate and the heat-spreading lid; and
a thermal conductive structure between the chip-containing structure and the heat-spreading lid, wherein the thermal conductive layer comprises an intermetallic compound material containing first metallic elements and second metallic elements, and the intermetallic compound material extends into the heat-spreading lid.

17. The package structure as claimed in claim 16, wherein the intermetallic compound material contains first metallic elements and second metallic elements, and the first metallic elements have a melting point lower than about 160 degrees C.

18. The package structure as claimed in claim 16, further comprising:
a thermal conductive layer between the chip-containing structure and the heat-spreading lid, wherein the thermal conductive layer is adjacent to the thermal conductive structure, and the thermal conductive layer has a lower melting point than the thermal conductive structure.

19. The package structure as claimed in claim 18, wherein the thermal conductive structure surrounds at least one corner of the thermal conductive layer.

20. The package structure as claimed in claim 16, further comprising:
a second chip-containing structure spaced apart from the chip-containing structure; and
a thermal conductive layer between the second chip-containing structure and the heat-spreading lid, wherein the thermal conductive layer is adjacent to the thermal conductive structure, the thermal conductive layer is made of indium, and the thermal conductive structure contains indium.
